(19) United States
(12) Patent Application Publication
(10) Pub. No.: US 2010/0308471 A1
(43) Pub. Date: Dec. 9, 2010

(54) ELECTRONIC DEVICE AND METHOD FOR MANUFACTURING THE SAME

(75) Inventors: Hayato Korogi, Hyogo (JP); Toru Hinomura, Osaka (JP); Atsushi Nishimura, Hyogo (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/858,248

(22) Filed: Aug. 17, 2010

Related U.S. Application Data
(63) Continuation of application No. PCT/JP2009/004057, filed on Aug. 24, 2009.

(30) Foreign Application Priority Data
Sep. 26, 2008 (JP) 2008-248998
Sep. 30, 2008 (JP) 2008-255219

(51) Int. Cl. H01L 23/538; H01L 21/768; H05K 1/11

(52) U.S. Cl. 257/774; 438/455; 174/266; 438/107; 257/E21.575; 257/E23.169

(57) ABSTRACT

An electronic device includes: a first substrate; and a second substrate on which the first substrate is mounted and which is electrically connected to the first substrate in at least one predetermined area. The predetermined area includes at least two through vias running through the first substrate, and an interconnect provided in the second substrate. The at least two through vias are electrically connected together via the interconnect.

### CROSS-REFERENCE TO RELATED APPLICATION

This is a continuation of PCT International Application PCT/JP2009/004057 filed on Aug. 24, 2009, which claims priority to Japanese Patent Application No. 2008-248998 filed on Sep. 26, 2008 and Japanese Patent Application No. 2008-255219 filed on Sep. 30, 2008. The disclosures of these applications including the specifications, the drawings, and the claims are hereby incorporated by reference in its entirety.

### BACKGROUND

In recent years, along with demands for increasing the degree of integration and the functionality of semiconductor integrated circuits, there are also demands for reducing the size thereof and the thickness thereof. In order to satisfy such demands, three-dimensional semiconductor apparatuses with increased semiconductor packaging densities have been proposed in the art. Three-dimensional semiconductor apparatuses are a technique in which a plurality of semiconductor chips and elements are stacked and connected together, thereby achieving high-density packaging.

Where a plurality of semiconductor chips are stacked together, an alignment method as follows is typically employed. That is, a semiconductor chip to be on the lower side is positioned by optically recognizing the position of a terminal (through electrode), etc., formed thereon. Then, a semiconductor chip to be laid over (i.e., to be on the upper side) is similarly positioned by recognizing the position thereof, and the two semiconductor chips are attached together.

With this method, however, a misalignment occurring during the attachment cannot be recognized. Therefore, if they are actually attached together misaligned, the electrical connection between the two semiconductor chips cannot be established. That is, this method has a disadvantage that it may lead to a decrease in the yield.

In view of this, such an alignment method as shown in Document 1 (Japanese Laid-Open Patent Publication No. 2005-175263) has been proposed in the art. Referring to FIG. 31, an alignment method in which a misalignment occurring during the attachment of semiconductor chips is reduced will now be described.

With the method of Document 1, a through electrode 10a is formed in the semiconductor chip mounting region of a substrate 1, and an alignment mark 20a having the same structure as the through electrode 10a is formed in the semiconductor chip non-mounting region of the substrate 1, as shown in FIG. 31.

Then, a through electrode 15 is formed in a semiconductor chip 30 to be laid over (to be on the upper side) at a position corresponding to the through electrode 10a of the substrate 1. In this way, each semiconductor chip stacked on the substrate 1 can be positioned by using the same reference (the alignment mark 20a), thereby realizing an accurate position control.

### SUMMARY

However, the method of Document 1 is also an indirect alignment method. Therefore, it is unknown whether an optimal alignment position is actually achieved.

In the future, along with demands for further enhancing the degree of integration and the functionalities of semiconductor integrated circuits, it is expected that there will also be a demand for further reducing the size and the thickness. With this trend, it is necessary to realize further miniaturization and increase in the degree of integration also for a plurality of semiconductor chips and elements used in a three-dimensional semiconductor apparatus, and it is expected that through electrodes will be smaller. Conventional methods and the method shown in Document 1 are all indirect alignment methods and are limited as to miniaturization.

The method of Document 1 is one where alignment marks are formed on a substrate and chips are placed according to the alignment marks, and therefore it is compatible with a case where chips are stacked on a wafer, but it is not compatible with wafer-to-wafer or chip-to-chip stacking.

In view of the above, the following description is directed to a three-dimensional semiconductor apparatus and a method for manufacturing the same, which improve the positional precision by directly detecting alignment positions and can be used for wafer-to-wafer or chip-to-chip stacking.

A first electronic device of the present disclosure includes: a first substrate; and a second substrate on which the first substrate is mounted and which is electrically connected to the first substrate in at least one predetermined area, wherein the predetermined area includes at least one pair of through vias running through the first substrate, and an interconnect provided in the second substrate, and the at least one pair of through vias are electrically connected together via the interconnect.

Such a first electronic device is an electronic device that is more accurate and more reliable than the conventional technique since the first substrate and the second substrate are stacked together while directly measuring the alignment therebetween, as will be described later.

Note that as a more specific embodiment of the first electronic device, at least two conductive portions may be formed in an uppermost layer of the first substrate, and the at least two through vias are electrically connected to the at least two conductive portions respectively and separately.

As an even more specific embodiment of the first electronic device, the at least two through vias may be formed in a peripheral portion within the predetermined area.

The electronic device may include a plurality of pairs of the through vias. Such an embodiment provides an electronic device that is more accurate and more reliable.

A second electronic device of the present disclosure includes: a first substrate; and a second substrate on which the first substrate is mounted and which is electrically connected to the first substrate in at least one predetermined area, wherein the predetermined area includes at least one first through via running through the first substrate, and at least one second through via running through the second substrate, and the at least one first through via and the at least one second through via are electrically connected together.

Such a second electronic device is an electronic device that is more accurate and more reliable than the conventional technique since the first substrate and the second substrate are stacked together while directly measuring the alignment therebetween, as will be described later.

Note that as an even more specific embodiment of the second electronic device, a first conductive portion may be provided in an uppermost layer of the first substrate, a second conductive portion may be provided in an uppermost layer of the second substrate, and the first conductive portion, the first through via, the second conductive portion and the second through via may be electrically connected together.

As an even more specific embodiment of the second electronic device, the first through via and the second through via may be formed in an peripheral portion within the predetermined area.

The electronic device may include a plurality of pairs of the first through vias and the second through vias. Such an embodiment provides an electronic device that is more accurate and more reliable.

A third electronic device of the present disclosure includes: a first substrate; and a second substrate on which the first substrate is mounted and which is electrically connected to the first substrate in at least one predetermined area, wherein the predetermined area includes at least one first through via running through the first substrate, a device isolation region formed in a semiconductor substrate of the second substrate, and at least one plug formed so as to be connected to the semiconductor substrate of the second substrate, the device isolation region is formed so as to surround a position of a lower end portion of the plug, and the at least one first through via and the at least one plug are electrically connected together.

Such a third electronic device is an electronic device that is more accurate and more reliable than the conventional technique since the first substrate and the second substrate are stacked together while directly measuring the alignment therebetween, as will be described later.

As a more specific embodiment of the third electronic device, a first conductive portion may be provided in an uppermost layer of the first substrate, a second conductive portion may be provided in an uppermost layer of the second substrate, and the first conductive portion, the first through via, the second conductive portion and the plug are electrically connected together.

As a more specific embodiment of the third electronic device, the first through via and the plug may be formed in a peripheral portion within the predetermined area.

The electronic device may include a plurality of pairs of the first through vias and the plugs. Such an embodiment provides an electronic device that is more accurate and more reliable.

Next, a first method for manufacturing an electronic device of the present disclosure includes the steps of: (a) forming at least one pair of through vias in a first substrate; (b) forming an interconnect in a second substrate; and (c) bonding together the first substrate and the second substrate, after the step (a) and the step (b), wherein the at least one pair of through vias are electrically connected together via the interconnect.

With the first method for manufacturing an electronic device, the first substrate can be mounted on the second substrate while directly measuring the alignment therebetween, and it is therefore possible to manufacture an electronic device in which the alignment is more accurate and more reliable than the conventional technique. Therefore, the yield of the electronic device manufacture is improved. Moreover, the method can be used in various cases, e.g., where the first substrate and the second substrate are both chips, both wafers, a chip and a wafer, etc.

That is, in the step (c), a current is allowed to flow through the at least two through vias via the interconnect, and the relative position displacement between the first substrate and the second substrate is observed by observing the current value thereof. Thus, it is possible to directly observe the alignment between the first substrate and the second substrate, and it is therefore possible to perform the mounting while reducing the misalignment as compared with indirect methods.

A second method for manufacturing an electronic device of the present disclosure includes the steps of: (a) forming at least one first through via in a first substrate; (b) forming at least one second through via in a second substrate; and (c) bonding together the first substrate and the second substrate after the step (a) and the step (b), wherein the at least one first through via and the at least one second through via are electrically connected together.

Note that it is preferred that in the step (c), a current is allowed to flow through the first through via and the second through via, and the bonding is performed while observing a current value thereof.

A third method for manufacturing an electronic device of the present disclosure includes the steps of: (a) forming at least one first through via in a first substrate; (b) forming a device isolation region in a semiconductor substrate of a second substrate; (c) forming at least one plug so as to be connected to the semiconductor substrate of the second substrate; and (d) bonding together the first substrate and the second substrate after the step (a) and the step (b), wherein the device isolation region is formed so as to surround a position of a lower end portion of the plug, and the at least one first through via and the at least one plug are electrically connected together.

Note that it is preferred that in the step (d), a current is allowed to flow through the first through via and the plug, and the bonding is performed while observing a current value thereof.

Also with the second method for manufacturing an electronic device and the third method for manufacturing an electronic device, there are similar advantages to those of the first method for manufacturing an electronic device, such as an accurate alignment, an improved production yield, etc.

Next, a fourth electronic device of the present disclosure includes: a first substrate; and a second substrate on which the first substrate is mounted and which is electrically connected to the first substrate in at least one predetermined area, wherein the predetermined area includes at least one through via running through the first substrate, a first interconnect provided in the first substrate so as to surround a portion of the predetermined area and so as to prevent opposite ends thereof from contacting each other, a pair of terminal pads provided on the first substrate and electrically connected respectively to the opposite ends of the first interconnect, and at least one conductive portion provided on the second substrate and connected to the through via.

The fourth electronic device of the present disclosure is an electronic device that is more accurate and more reliable than the conventional technique since the first substrate and the second substrate are stacked together while directly measuring the alignment therebetween, as will be described later.

Note that at least one of the through vias may be located outside the first interconnect. At least one of the through vias may be located inside the first interconnect.

Thus, the through vias may be located either outside or inside the first interconnect, and in a case where a plurality of through vias are provided, they may be located outside and inside the first interconnect. Note however that it is preferred that the through vias are located inside the first interconnect, in which case the advantage of an accurate alignment is more pronounced.

It is preferred that the predetermined area further includes a second interconnect provided so as to surround the first interconnect and so as to prevent opposite ends thereof from contacting each other.

In this way, it is possible to obtain an electronic device in which the first substrate and the second substrate are aligned together more reliably.

A fifth electronic device of the present disclosure includes: a first substrate; and a second substrate on which the first substrate is mounted and which is electrically connected to the first substrate in at least one predetermined area, wherein the predetermined area includes at least one through via running through the first substrate, an inductor provided in the first substrate above the through via, and at least one conductive portion provided on the second substrate and connected to the through via.

A sixth electronic device of the present disclosure includes: a first substrate; and a second substrate on which the first substrate is mounted and which is electrically connected to the first substrate in at least one predetermined area, wherein the predetermined area includes at least one through via running through the first substrate, means provided in the first substrate for generating a magnetic field in the predetermined area in a direction in which the through via extends, and at least one conductive portion provided on the second substrate and connected to the through via.

Such fifth and sixth electronic devices of the present disclosure are also electronic devices that are more accurate and more reliable than the conventional technique.

In the fourth to sixth electronic devices of the present disclosure, it is preferred that the first substrate and the second substrate are electrically connected together in a plurality of predetermined areas.

In this way, it is possible to obtain an electronic device in which the first substrate and the second substrate are aligned together more reliably.

The through via may be made of a material whose main component is Cu.

It is preferred that the through via is made of a material containing a ferromagnetic substance.

It is preferred that the conductive portion is made of a material containing a ferromagnetic substance.

The conductive portion may have a layered structure including a Cu film, and a cap film formed on the Cu film and made of a material containing a ferromagnetic substance.

It is preferred that the ferromagnetic substance is at least one of Fe, Co, Ni and Gd.

When the through via and the conductive portion use such materials and structures as described above, the advantages of the present disclosure are more evident.

Next, a fourth method for manufacturing an electronic device of the present disclosure includes the steps of: (a) forming at least one through via running through a first substrate in a predetermined area of the first substrate; (b) forming a first interconnect in the first substrate so as to surround a portion of the predetermined area and so as to prevent opposite ends thereof from contacting each other; (c) forming a pair of terminal pads on the first substrate so as to be electrically connected respectively to the opposite ends of the first interconnect after the steps (a) and (b); (d) forming at least one conductive portion on the second substrate so as to be electrically connected to the through via; and (e) mounting the first substrate on the second substrate and electrically connecting together the conductive portion and the through via after the steps (c) and (d).

Note that it is preferred that in the step (e), a current is allowed to flow through the first interconnect via the pair of terminal pads to thereby provide the through via with a magnetic force, and the first substrate is mounted on the second substrate while observing the displacement caused by the attraction acting between the through via and the conductive portion.

With the fourth method for manufacturing an electronic device, first fourth substrate can be mounted on the second substrate while directly measuring the alignment therebetween, and it is therefore possible to manufacture an electronic device in which the alignment is more accurate and more reliable than the conventional technique. Therefore, the yield of the electronic device manufacture is improved. Moreover, the method can be used in various cases, e.g., where the first substrate and the second substrate are both chips, both wafers, a chip and a wafer, etc.

That is, in the step (e), an attraction acts between the conductive portion and the through via, which is given a magnetic force from the current flow through the first interconnect. It is possible to directly observe the alignment between the first substrate and the second substrate by observing the relative position displacement between the first substrate and the second substrate caused by the attraction, and it is therefore possible to perform the mounting while reducing the misalignment as compared with indirect methods.

A fifth method for manufacturing an electronic device of the present disclosure includes the steps of: (a) forming at least one through via running through a first substrate in a predetermined area of the first substrate; (b) forming an inductor in the first substrate above the through via after the step (a); (c) forming at least one conductive portion on the second substrate so as to be connected to the through via; and (d) mounting the first substrate on the second substrate and electrically connecting together the conductive portion and the through via after the steps (b) and (c).

Note that it is preferred that in the step (d), a current is allowed to flow through the inductor to thereby provide the through via with a magnetic force, and the first substrate is mounted on the second substrate while observing the displacement caused by the attraction acting between the through via and the conductive portion.

Also with the fifth method for manufacturing an electronic device, there are similar advantages to those of the fourth method for manufacturing an electronic device, such as an accurate alignment, an improved production yield, etc.

With the fourth and fifth methods for manufacturing an electronic device, it is preferred that the through via is formed by a material whose main component is Cu.

Such a material can be used as the material of the through via.

It is preferred that the through via is formed by a material containing a ferromagnetic substance.

In this way, a magnetic force can be generated in the through via more reliably.

It is preferred that the conductive portion is formed by a material containing a ferromagnetic substance.

In this way, an attraction more reliably acts on the conductive portion from the magnetic force generated in the through via.

It is preferred that the ferromagnetic substance is at least one of Fe, Co, Ni and Gd.

Specific elements of the ferromagnetic substance are as listed above.

As described above, with the electronic device of the present disclosure and the method for manufacturing the same, the attachment can be made while directly observing the position at which the misalignment is minimized, and it is therefore possible to improve the production yield of the electronic device. Moreover, it is compatible with the attachment of various elements such as wafer-to-wafer, chip-to-chip, etc.

### BRIEF DESCRIPTION OF THE DRAWINGS

FIG. 1 is a schematic cross-sectional view illustrating a structure of an example electronic device according to a first embodiment of the present disclosure.

FIGS. 2A-2D are diagrams showing the planar configuration for the example electronic device of the first embodiment.

FIGS. 3A and 3B represent the planar configuration for the example electronic device of the first embodiment, and FIGS. 3C-3E are schematic cross-sectional views illustrating a variation of the structure of the second wafer.

FIGS. 4A and 4B are schematic cross-sectional views illustrating the structure and formation method of the first wafer for the example electronic device of the first embodiment.

FIGS. 5A and 5B are schematic cross-sectional views, subsequent to FIG. 4B, illustrating the structure and formation method of the first wafer.

FIGS. 6A and 6B are schematic cross-sectional views illustrating the structure and formation method of the second wafer for the example electronic device of the first embodiment.

FIG. 7 is a schematic cross-sectional view, subsequent to FIG. 6B, illustrating the structure and formation method of the second wafer.

FIG. 8 is a schematic cross-sectional view illustrating an alignment method of the first embodiment.

FIG. 9 is a schematic plan view illustrating an alignment method of the first embodiment.

FIG. 10 is a schematic cross-sectional view illustrating a structure of an example electronic device according to a second embodiment of the present disclosure.

FIGS. 11A-11E are schematic plan views illustrating the second wafer according to a variation of the second embodiment.

FIG. 12 is a schematic cross-sectional view illustrating an alignment method for the example electronic device of the second embodiment.

FIG. 13 is a schematic cross-sectional view illustrating a structure of an example electronic device according to a third embodiment of the present disclosure.

FIGS. 14A-14G are schematic cross-sectional views illustrating the structure and formation method of the first wafer for the example electronic device of the third embodiment.

FIGS. 15A and 15B are schematic cross-sectional views illustrating the planar configuration of the first wafer for the example electronic device of the third embodiment.

FIGS. 16A-16D are schematic cross-sectional views illustrating the structure and formation method of the second wafer for the example electronic device of the third embodiment.

FIGS. 17A and 17B are a schematic cross-sectional view and a plan view illustrating an alignment method for the example electronic device of the third embodiment.

FIGS. 18A and 18B are schematic cross-sectional views illustrating the first wafer according to a variation of the third embodiment.

FIGS. 19A and 19B are schematic plan views illustrating the first wafer according to a variation of the third embodiment.

FIGS. 20A-20C are schematic plan views illustrating the first wafer according to a variation of the third embodiment.

FIGS. 21A-21F are schematic cross-sectional views illustrating the structure and formation method of the first wafer for the example electronic device of the fourth embodiment of the present disclosure.

FIGS. 22A-22C are schematic plan views illustrating the structure of the first wafer of the fourth embodiment.

FIGS. 23A and 23B are a schematic cross-sectional view and a plan view illustrating an alignment method for the example electronic device of the fourth embodiment.

FIGS. 24A and 24B are schematic plan views illustrating the first wafer according to a variation of the fourth embodiment.

FIGS. 25A-25C are diagrams further illustrating the alignment method of the first and second embodiments.

FIG. 26 is a diagram illustrating still another example of the alignment method of the first and second embodiments.

FIG. 27 is a diagram illustrating a wafer when the alignment method of FIG. 26 is carried out.

FIGS. 28A and 28B are diagrams further illustrating the alignment method of the third and fourth embodiments.

FIG. 29 is a diagram illustrating still another example of the alignment method of the third and fourth embodiments.

FIG. 30 is a diagram illustrating a wafer when the alignment method of FIG. 29 is carried out.

FIG. 31 is a schematic cross-sectional view illustrating an alignment method as a technical background.

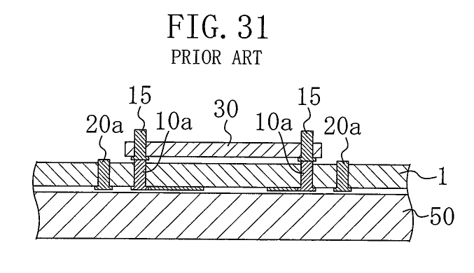

### DETAILED DESCRIPTION

Embodiments of the present disclosure will now be described with reference to the drawings. Note however that the shape, material, sizes, etc., of various elements shown in various figures to be described below are all illustrative, and while they are preferred examples, they are not limited to those shown herein. They may be changed as necessary without being bound by the disclosure herein without departing from the technical gist hereof. While the wafer-to-wafer attachment is primarily discussed, similar descriptions hold true and similar advantages can be obtained also with wafer-to-chip attachment and chip-to-chip attachment.

### First Embodiment

An electronic device according to a first embodiment of the present disclosure and a method for manufacturing the same will be described.

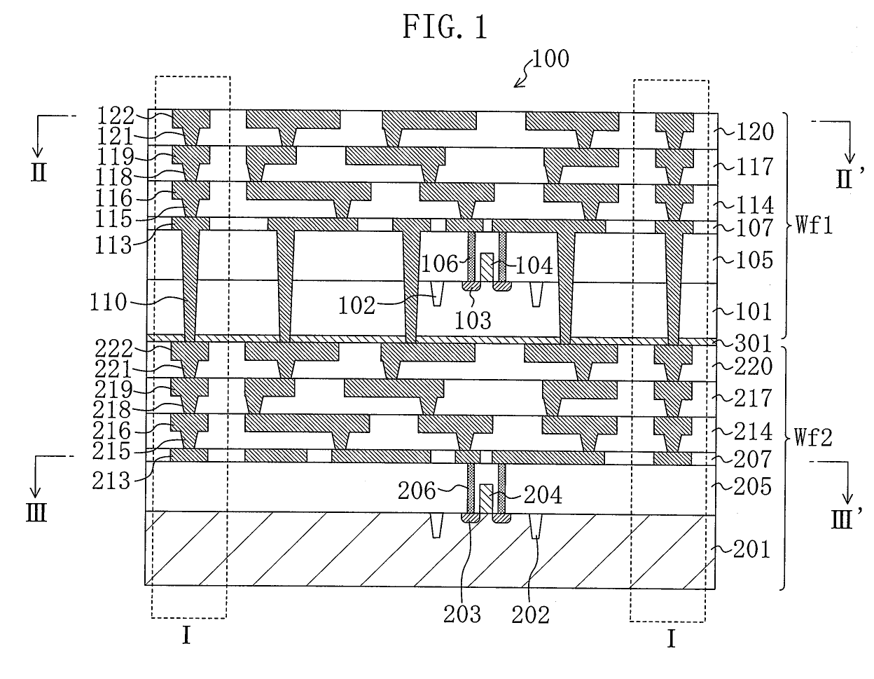

FIG. 1 shows a schematic cross-sectional view of a main part of an example electronic device 100 of the present embodiment. The electronic device 100 includes a first wafer Wf1, and a second wafer Wf2 on which the first wafer Wf1 is mounted. They are stacked together with the first wafer Wf1 being on the upper side and the second wafer Wf2 on the lower side, and are bonded together by an adhesive 301. In a predetermined area, the first wafer Wf1 and the second wafer Wf2 are electrically connected together. More specifically, there is provided a through via 110 running through a semiconductor substrate 101 of the first wafer Wf1 in the predetermined area, and the first wafer Wf1 and the second wafer Wf2 are electrically connected together via the through via 110.

Note that it is assumed that the figures of the embodiments each show one chip area of the wafer. The chip area can be assumed as a predetermined area. A chip area is an area to be an individual chip when the wafer is divided, and a plurality of MOS elements, etc., are formed on the semiconductor substrate 101 in each chip area.

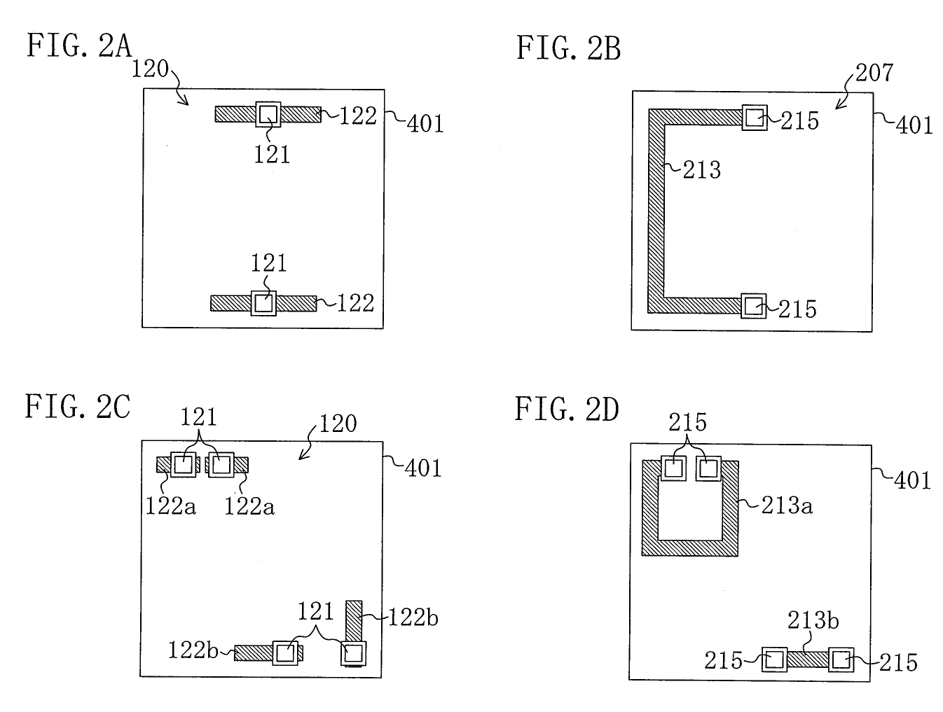

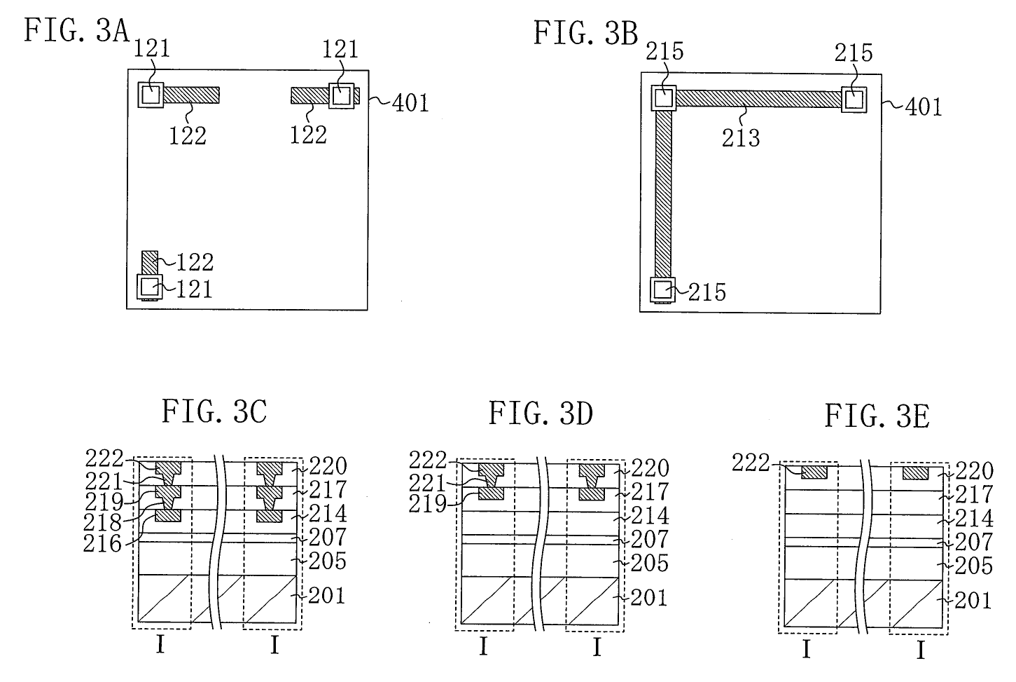

Next, the planar arrangement of an interconnect 213 on the second wafer Wf2 located in the lower portion of the electronic device 100 will be described. FIGS. 2A-2D and FIGS. 3A-3E are diagrams illustrating the second wafer Wf2.

FIG. 2A shows an example of the planar shape of a pair of (two) interconnects 122, as a cross section taken along line II-II′ in the area I of FIG. 1. Now, the area I in FIG. 1 denotes an area near the peripheral portion of one chip area. FIG. 2A shows the planar shape of the pair of interconnects 122 in one chip area 401. Now, when the area I of FIG. 1 is sliced along a line parallel to line interconnects 119, 116, 113, 222, 219 and 216 (not shown) have a similar planar shape to that of the interconnects 122. Note however that the arrangement is not limited to such an arrangement. Now, it is preferred that the pair of interconnects 113, 222 are located near the peripheral portion of the chip area 401. Moreover, it is preferred that the pair of interconnects 113, 222 are located opposite to each other with respect to the center of the chip area 401. Now, the pair of interconnects 113, 222 correspond to interconnects connected to through electrodes of the wafer.

FIG. 2B shows an example of the planar shape of the interconnect 213, as a cross section taken along line in the area I of FIG. 1. Now, the area I in FIG. 1 denotes an area near the peripheral portion of one chip area. It is preferred that the interconnect 213 is located near the peripheral portion of the chip area 401.

As can be seen from FIGS. 1, 2A and 2B, the pair of interconnects 122 are electrically connected together through vias 121, 118, 115, 221, 218 and 215, the interconnects 119, 116, 113, 222, 219 and 216, the through via 110, and the interconnect 213.

This gives an advantage of an easier alignment as will later be described in detail.

FIGS. 2C and 2D show variations of FIGS. 2A and 2B, respectively.

FIG. 2C shows an example of the planar shape of a pair of interconnects 122a and a pair of interconnects 122b, as a cross section taken along line II-II′ in the area I of FIG. 1. Now, the area I in FIG. 1 denotes an area near the peripheral portion of one chip area. When the area I of FIG. 1 is sliced along a line parallel to line pairs of interconnects 119a-119b, 116a-116b, 113a-113b, 222a-222b, 219a-219b and 216a-216b (not shown) have a similar planar shape to that of the interconnects 122a and 122b. Note however that the arrangement is not limited to such an arrangement.

Now, it is preferred that the pair of interconnects 113a-113b, 222a-222b are located near the peripheral portion of the chip area 401. Moreover, it is preferred that the pair of interconnects 113a-113b, 222a-222b are located opposite to each other with respect to the center of the chip area 401. The pair of interconnects 113a-113b, 222a-222b correspond to interconnects connected to through electrodes of the wafer.

FIG. 2D shows an example of the planar shape for an interconnect 213a and an interconnect 213b, as a cross section taken along line in the area I of FIG. 1. Now, the area I in FIG. 1 denotes an area near the peripheral portion of one chip area. It is preferred that the interconnect 213a and the interconnect 213b are located near the peripheral portion of the chip area 401.

As can be seen from FIGS. 1, 2C and 2D, the pair of interconnects 122a are electrically connected together through the vias 121, 118, 115, 221, 218 and 215, the interconnects 119, 116, 113, 222, 219 and 216, the through via 110, and the interconnect 213a. The pair of interconnects 122b has a configuration similar to that of the pair of interconnects 122a.

As described above, there may be a plurality of pairs of interconnects. Providing more than one gives an advantage of an improved alignment precision.

FIGS. 3A and 3B show variations of FIGS. 2A and 2B, respectively.

FIG. 3A shows an example of the planar shape of a triplet interconnects 122, as a cross section taken along line II-II′ in the area I of FIG. 1. Now, the area I in FIG. 1 denotes an area near the peripheral portion of one chip area. When the area I of FIG. 1 is sliced along a line parallel to line II-II′, the triplet interconnects 119, 116, 113, 222, 219 and 216 have a similar planar shape (not shown). Note however that the arrangement is not limited to such an arrangement.

It is preferred that the triplet interconnects 113, 222 are each located near the peripheral portion of the chip area 401. It is preferred that the interconnects 113 and 222 are located near the peripheral portion of the chip area 401. The triplet interconnects 113 and 222 correspond to interconnects connected to through electrodes of the wafer.

FIG. 3B shows an example of the planar shape of the interconnect 213, as a cross section taken along line III-III′ in the area I of FIG. 1. Now, the area I in FIG. 1 denotes an area near the peripheral portion of one chip area. It is preferred that the interconnect 213 is located near the peripheral portion of the chip area 401.

As can be seen from FIGS. 1, 3A and 3B, two interconnects of the triplet interconnects 122 are electrically connected together through the vias 121, 118, 115, 221, 218 and 215, the interconnects 119, 116, 113, 222, 219 and 216, the through via 110, and the interconnect 213.

As described above, there may be a plurality of through vias connected to the interconnect 213. Providing more than one gives an advantage of an improved alignment precision. There is no problem with the provision of a through via that does not form a pair.

FIGS. 3C-3E show variations of the second wafer Wf2 in the area I of FIG. 1. While the pair of interconnects 122 are electrically connected together through the interconnect 213 in FIGS. 1, 2A-2D, 3A and 3B, the interconnects 122 may be electrically connected together through the interconnect 216 as shown in FIG. 3C. The pair of interconnects 122 may be electrically connected together through the interconnect 219 as shown in FIG. 3D. The pair of interconnects 122 may be electrically connected together through the interconnect 222 as shown in FIG. 3E.

By electrically connecting the pair of interconnects 122 together using an interconnect in as higher a layer as possible as shown in FIGS. 3C-3E, the space of lower layers can be used efficiently, thereby giving an advantage of an increased degree of design freedom.

Note that such various variations as described above may be combined with one another as necessary.

Now, the more detailed structure and formation method of the first wafer Wf1 and the second wafer Wf2 will be described.

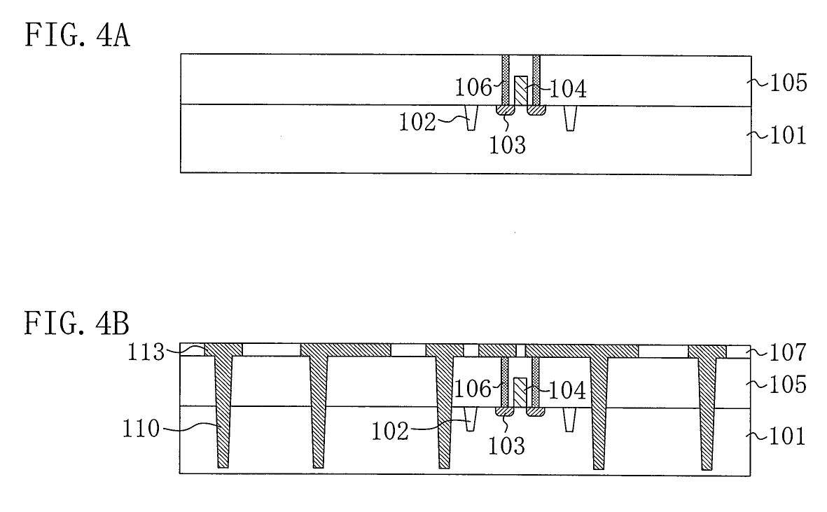

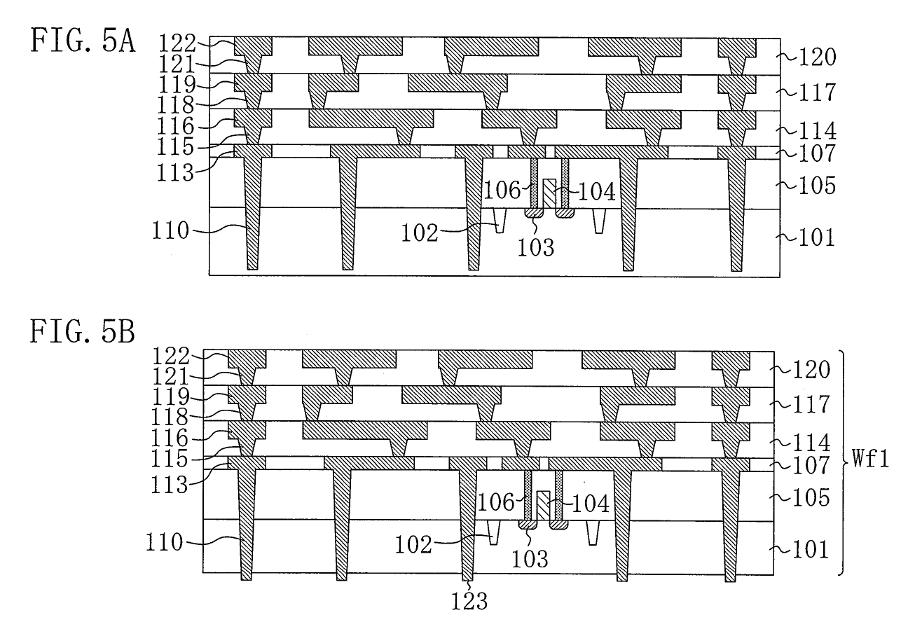

FIGS. 4A and 4B and FIGS. 5A and 5B are schematic cross-sectional views illustrating the structure and formation method of the first wafer Wf1 located in the upper portion of the electronic device 100.

In order to form the first wafer Wf1, the step of FIG. 4A is first performed. Here, there is provided the semiconductor substrate 101, which is a thin plate having a generally circular planar shape, for example. The semiconductor substrate 101 is a substrate made of an n-type or p-type single crystal silicon, for example.

A device isolation 102 is formed in the semiconductor substrate 101. This is formed by forming a groove on the upper surface of the semiconductor substrate 101 by a lithography method and a dry etching method, and filling the groove with a silicon oxide film (SiO₂) by a chemical vapor deposition (CVD) method, for example.

Then, a metal oxide semiconductor (MOS) element, for example, is formed in an active region of the semiconductor substrate 101 surrounded by the device isolation 102. The MOS element includes semiconductor regions 103 for the source and drain, a gate electrode 104, etc.

Now, the semiconductor region 103 is formed by adding a predetermined impurity (phosphorus (P) or arsenic (As), for example, for an n-channel type, and boron (B), for example, for a p-channel type) to the semiconductor substrate 101. The gate electrode 104 is formed as an electrode made of polysilicon on the semiconductor substrate 101 with a gate insulating film made of a silicon oxide film (SiO₂), for example, interposed therebetween.

Then, an insulating film 105 of a silicon oxide film, or the like, for example, is deposited so as to cover the semiconductor substrate 101. Then, an excess of the silicon oxide film deposited on the gate electrode 104 is removed by a chemical mechanical polishing (CMP), thereby flattening the structure. Then, a plug 106, which is to be connected to the semiconductor region 103 and the gate electrode 104 and electrically connected to interconnects to be formed in a subsequent step, is formed so as to be buried in the insulating film 105 (note however that the plug to be connected to the gate electrode 104 is not shown). The plug 106 is formed by a metal such as tungsten (W), aluminum (Al), or copper (Cu), for example.

Then, the step of FIG. 4B is performed. First, a liner film (not shown) is deposited across the entire surface so as to cover the plug 106 and the insulating film 105. This is, for example, formed as a silicon nitride film (SiN) having a thickness of about 30 nm by a CVD method. A silicon oxide film may be used instead of a silicon nitride film.

Then, through via holes are formed by using a lithography method and a dry etching method. They are formed to such a depth as to run through the liner film and the insulating film 105 and to further cut into about 1/7 to ⅛, for example, of the semiconductor substrate 101. If the thickness of the semiconductor substrate 101 is 750 μm, the depth is 100 μm.

Then, a barrier film made of tantalum (Ta)/tantalum nitride (TaN) and a copper (Cu) film are deposited in this order by using a sputtering method and a plating method so as to fill the through via holes and cover the liner film. Then, portions of the barrier film and the copper film overflowing onto the liner film are removed by using a CMP method, thereby forming the through vias 110 so as to fill the through via holes.

Note that while a layered film of a Ta film and a TaN film is used here as the barrier film, the barrier film may be made of only one of a Ta film and a TaN film. While copper is used as a material of a conductive film that fills the through via holes, it may alternatively be silver (Ag), aluminum (Al), or an alloy thereof, etc.

It is preferred that an insulative film is formed, before the barrier film is formed, on the side wall of the through via hole. Alternatively, the through vias 110 may be surrounded by an insulating substance, instead of forming the insulative film.

Then, the interconnect 113 is formed. For this, first, an insulating film 107 made of a silicon oxide film having a thickness of 200 nm is deposited by a CVD method, for example, so as to cover the through via 110 and the liner film. Then, a plurality of interconnect grooves are formed spaced apart from one another by a lithography method and a dry etching method so as to run through both the insulating film 107 and the liner film.

Then, a barrier film made of tantalum (Ta)/tantalum nitride (TaN) and a copper (Cu) film are deposited in this order by a sputtering method and a plating method so as to fill the interconnect grooves and cover the insulating film 107.

Then, unnecessary portions of the barrier film and the copper film overflowing onto the insulating film 107 are removed by using a CMP method, thereby forming the interconnects 113 made of the barrier film and the copper film and filling the interconnect grooves.

Again, the barrier film is not limited to a layered structure of Ta film/TaN film, and it may be solely a Ta film, a TaN film, or the like. A film made of silver, aluminum or an alloy thereof may be used instead of the copper film.

Then, the step of FIG. 5A is performed. Here, a plurality of insulating films 114, 117 and 120 layered together, and interconnect structures (vias 115, 118 and 121 and interconnects 116, 119 and 122) to be buried therein are formed.

First, the insulating film 114 made of a silicon oxide film having a thickness of 400 nm is deposited by a CVD method, for example, so as to cover the insulating film 107 including the interconnects 113. Then, a plurality of via holes and interconnect grooves connected to the top of the plurality of via holes are formed in the insulating film 114 by a lithography method and a dry etching method.

Then, a barrier film made of tantalum (Ta)/tantalum nitride (TaN) and a copper (Cu) film are deposited in this order by a sputtering method and a plating method so as to fill the via holes and the interconnect grooves and cover the insulating film 114.

Then, unnecessary portions of the barrier film and the copper film overflowing onto the insulating film 114 are removed by using a CMP method, thereby forming the vias 115 and the interconnects 116 having a structure in which the via holes and the interconnect grooves are filled by the barrier film and the copper film. Note that the via 115 that connects to a desired position of the interconnect 113 can be formed by setting the position of the via hole as necessary.

Moreover, similar steps are repeated to form the insulating film 117 formed on the insulating film 114 and the via 118 and the interconnect 119 buried therein, and an insulating film 120 formed on the insulating film 117 and the via 121 and the interconnect 122 buried therein, thus forming a multi-layer interconnect structure. While the total number of interconnect layers is four, this is an example, and the number is not limited to this.

Note that the insulating films 114, 117 and 120 each have a single-layer structure of a silicon oxide film in the present embodiment. However, it may alternatively be a single-layer structure of another material, or a layered film of silicon oxide film/silicon nitride film, etc. The barrier film is not limited to a layered structure of Ta film/TaN film, and may be solely a Ta film, a TaN film, or the like. Moreover, a film of silver, aluminum or an alloy thereof may be used instead of a copper film.

Then, the step of FIG. 5B is performed. Here, a thinning process is performed on the semiconductor substrate 101 from the reverse surface thereof so that the lower end portion of the through via 110 is exposed as a through via bottom 123 on the reverse surface side of the semiconductor substrate 101.

As the thinning process, for example, the reverse surface of the semiconductor substrate 101 is first polished to a desired thickness, and then a polish process having both mechanical and chemical aspects such as a CMP method is performed. At this point, the through via bottom 123 is not exposed. Then, the reverse surface of the semiconductor substrate 101 is etched by a wet etching method so that the through via bottom 123 is exposed.

As another example of the thinning process, a CMP method and a wet etching method may be used without performing the polish. Moreover, the thinning process may be performed by only a CMP method or by only a wet etching method.

The first wafer Wf1 located in the upper portion of the electronic device 100 is formed as described above.

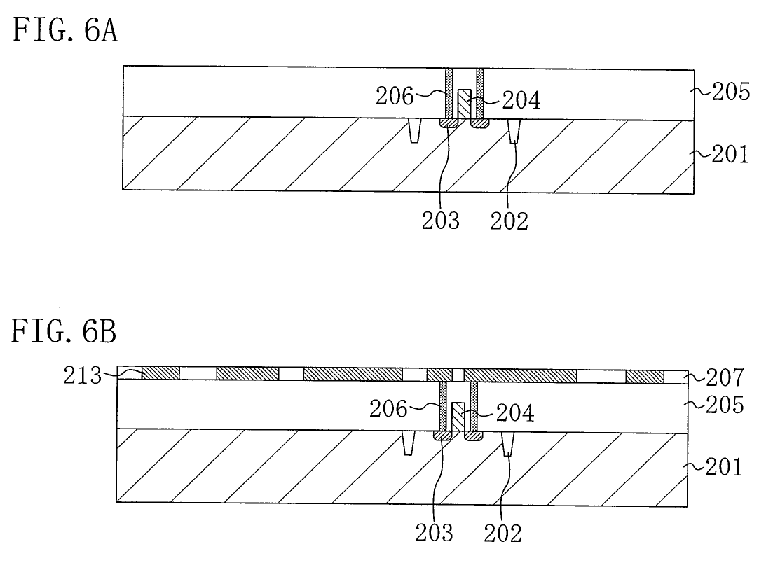

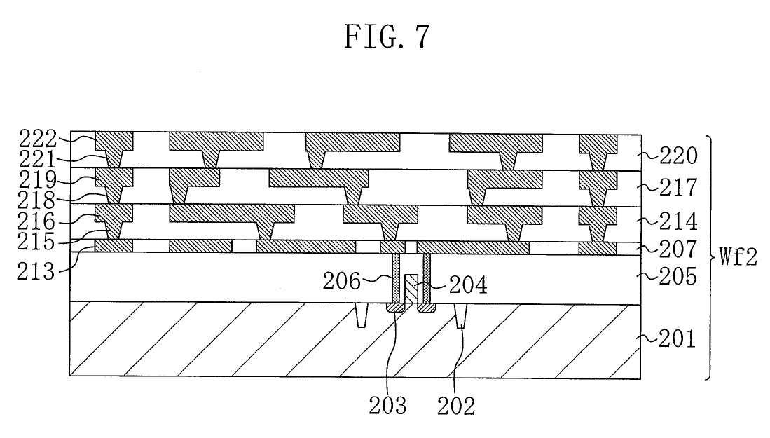

Next, FIGS. 6A and 6B and FIG. 7 are schematic cross-sectional views illustrating the structure and formation method of the second wafer Wf2 located in the lower portion of the electronic device 100.

First, a structure shown in FIG. 6A is formed. This is similar to the structure shown in FIG. 5A for the first wafer Wf1, the only difference being the reference numerals. That is, an active region is defined by a device isolation 202 on a semiconductor substrate 201, and a MOS element including a semiconductor region 203, a gate insulating film (not shown) and a gate electrode 204 is formed in the active region. An insulating film 205 is formed so as to cover the semiconductor substrate 201 including the MOS element, and a plug 206 is formed so as to reach the semiconductor region 203, etc., through the insulating film 205. These can be formed in a similar manner to that described above for the first wafer Wf1. Note however that the second wafer Wf2 does not need to have a similar structure to that of the first wafer Wf1, but may have a different structure.

Then, the step shown in FIG. 6B is performed. First, an insulating film 207 of a silicon oxide film having a thickness of 200 nm is deposited by a CVD method, for example, so as to cover the plug 206 and the insulating film 205. Then, a plurality of interconnect grooves are formed on the insulating film 207 spaced apart from one another by a lithography method and a dry etching method.

Then, a barrier film made of tantalum (Ta)/tantalum nitride (TaN) and a copper (Cu) film are deposited in this order by a sputtering method and a plating method so as to fill the interconnect grooves and cover the insulating film 207.

Then, unnecessary portions of the barrier film and the copper film overflowing onto the insulating film 207 are removed by using a CMP method, thereby forming the interconnects 213 made of the barrier film and the copper film and filling the interconnect grooves. Note that by setting the positions of the interconnect grooves, the interconnect 213 can be placed at any position so that, for example, it is connected to the top of the plug 206.

Again, the barrier film is not limited to a layered structure of Ta film/TaN film, and it may be solely a Ta film, a TaN film, or the like. A film made of silver, aluminum or an alloy thereof may be used instead of the copper film.

Note that the insulating film 107 has a single-layer structure of a silicon oxide film in the present embodiment. However, it may alternatively be a single-layer structure of another material, or a layered film of silicon oxide film/silicon nitride film, etc.

Then, the step shown in FIG. 7 is performed. Here, a plurality of insulating films 214, 217 and 220 layered together, and interconnect structures (vias 215, 218 and 221 and interconnects 216, 219 and 222) to be buried therein are formed.

These can be formed in a similar manner to that described above for the first wafer Wf1 with reference to FIG. 5A, for example. Note however that a different method may be used.

Since the interconnect 222 located in the uppermost layer needs to be connected to the through via bottom 123 in the first wafer Wf1, it is formed at a position appropriate therefor. The interconnects 216 and 219 in other layers and vias 215, 218 and 221 for connecting interconnects of different layers may be arranged in any manner.

The second wafer Wf2 located in the lower portion of the electronic device 100 is formed as described above.

Then, the first wafer Wf1 is aligned with and mounted on the second wafer Wf2, and the wafers are bonded together. The bonding step will now be described.

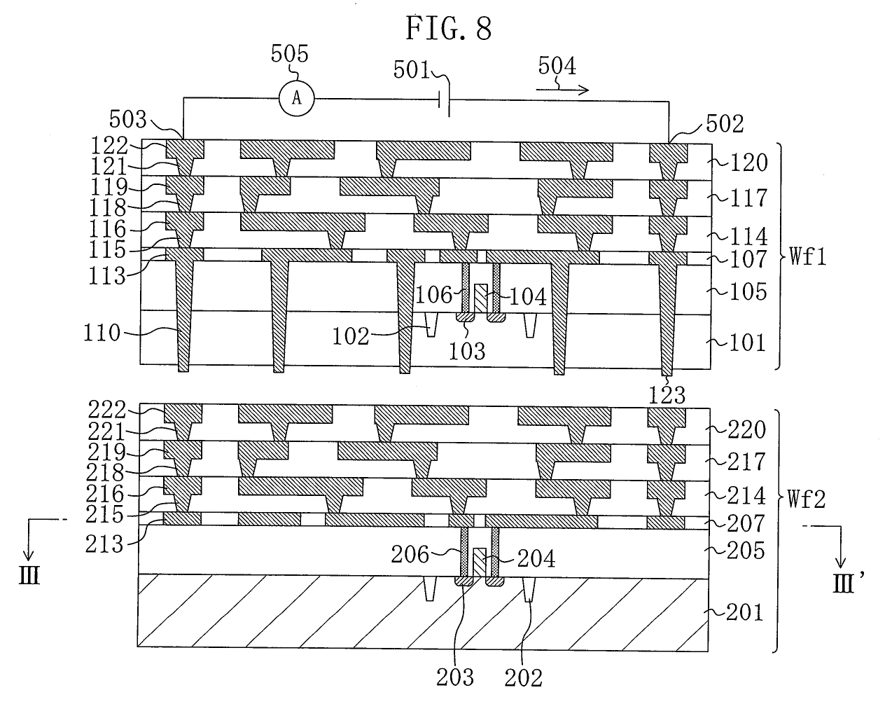

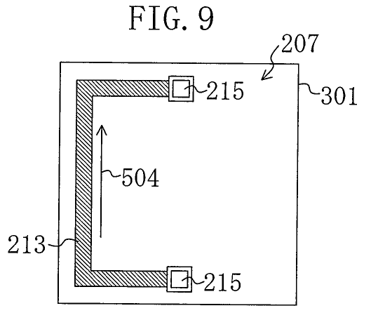

FIGS. 8 and 9 are a cross-sectional view and a plan view illustrating a alignment method for the step of bonding together the first wafer Wf1 and the second wafer Wf2.

First, the lower second wafer Wf2 is provided, and the upper first wafer Wf1 is placed thereon so that the reverse surface thereof faces the principal surface of the second wafer Wf2.

Then, the relative positions of the second wafer Wf2 and the first wafer Wf1 are aligned with each other. Specifically, the interconnect 222 of the uppermost layer of the second wafer Wf2 is aligned with the corresponding through via bottom 123 on the reverse surface of the first wafer Wf1.

Moreover, the opposing surfaces of the wafers are brought closer to each other, and the interconnect 222 of the uppermost layer of the second wafer Wf2 is brought into contact with the through via bottom 123 of the first wafer Wf1 so as to electrically connect them together. Thus, the first wafer Wf1 and the second wafer Wf2 are electrically connected together.

Then, the insulative adhesive 301 is injected into the gap between the first wafer Wf1 and the second wafer Wf2 (see FIG. 1), thereby bonding together the first wafer Wf1 and the second wafer Wf2, which have been stacked together, and thus ensuring the mechanical strength.

After bonding together the first wafer Wf1 and the second wafer Wf2, the wafers are cut into chips, thereby obtaining individual chips (the electronic devices 100). An electronic device obtained as described above has a three-dimensional structure in which a plurality of (two here) chips are stacked together. That is, semiconductor circuits, etc., provided on a plurality of chips are electrically connected together through the through vias, thereby forming a single semiconductor integrated circuit as a whole.

Now, the alignment between the first wafer Wf1 and the second wafer Wf2 will be further described.

An alignment to a certain degree is performed by using an optical alignment method, or the like. Then, as shown in FIGS. 8 and 9, opposing terminals connected to a power supply 501 are connected respectively to connection pads 502 and 503 formed on the interconnect 122 of the uppermost layer of the upper first wafer Wf1. Then, the power supply is turned on to apply a voltage, thereby allowing a current 504 to flow. Then, if the through via bottom 123 electrically connected to the connection pads 502 and 503 of the upper first wafer Wf1 is connected to the interconnect 222 of the uppermost layer of the lower second wafer Wf2, the current 504 flows via the interconnect 213 of the lower second wafer Wf2. Then, the current value of the current 504 can be monitored (observed) through an ammeter 505.

Now, if the upper first wafer Wf1 and the lower second wafer Wf2 are not aligned together, no current flows. When the through via bottom 123 of the upper first wafer Wf1 lies over the interconnect 222 of the uppermost layer of the lower second wafer Wf2 but is not completely connected thereto, the resistance increases and therefore the current value decreases. In contrast, the current value is maximized when there is a complete connection.

In view of this, the upper first wafer Wf1 is translated or rotated by small amounts with respect to the principal surface of the lower second wafer Wf2 while monitoring the current value. Then, a position across the range of movement at which the current value is maximized is determined as the optimal position.

With such an alignment method, the wafers can be attached together while directly observing the optimal position at which the misalignment is minimized, and it is therefore possible to perform a more accurate and appropriate alignment as compared with the background art which is an indirect alignment. Therefore, the yield of the electronic device manufacture is improved. Such a method is not limited to an alignment between wafers, but may also be compatible with an alignment between chips, an alignment of a chip with a wafer, etc.

### Second Embodiment

Next, an electronic device according to a second embodiment of the present disclosure and a method for manufacturing the same will be described.

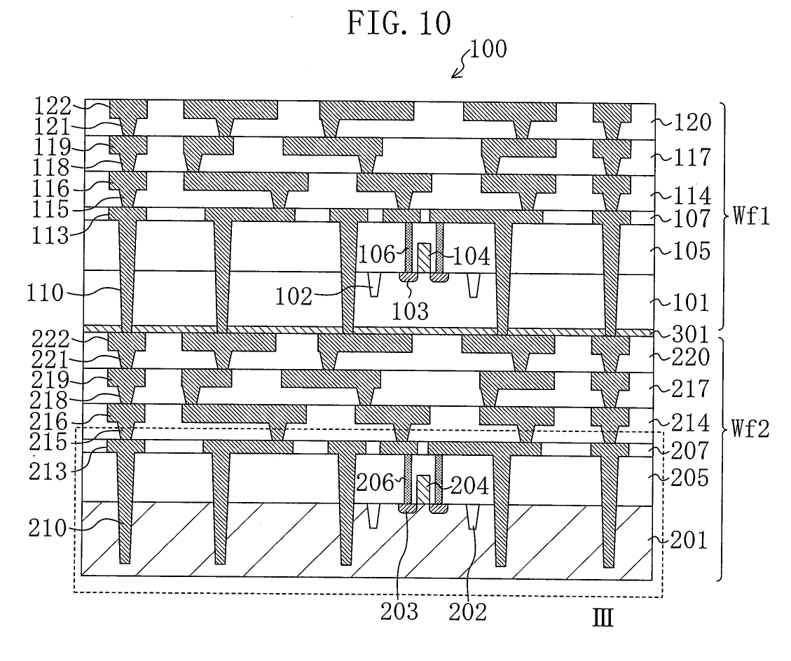

FIG. 10 shows an example electronic device 100 of the present embodiment. The electronic device 100 has a structure in which two wafers are stacked together, as does the electronic device 100 of the first embodiment. Note however that the first wafer Wf1 to be on the upper side and the second wafer to be on the lower side both have the same structure as the first wafer Wf1 (see FIG. 1) of the first embodiment. That is, the first embodiment and the second embodiment differ from each other in the structure and the manufacturing method for the second wafer Wf2 to be formed on the lower side. Note however that although FIG. 10 shows a structure in which two wafers are stacked together by using the second wafer Wf2, which is formed by omitting the step of exposing the through via bottom, the second wafer Wf2 in which the through via bottom is exposed may be used.

Note that the first wafer Wf1 and the second wafer Wf2 of the present embodiment may be manufactured in a similar manner to the first wafer Wf1 of the first embodiment.

In FIG. 10, the interconnect 122 of the uppermost layer of the first wafer Wf1 is electrically connected to the lower end of a through via 210 of the second wafer Wf2 or the semiconductor substrate region near the lower end through the interconnects 119, 116, 113, 222, 219, 216 and 213, the vias 121, 118, 115, 221, 218 and 215 and the through vias 110 and 210. Such an electrical connection gives an advantage of an easier alignment.

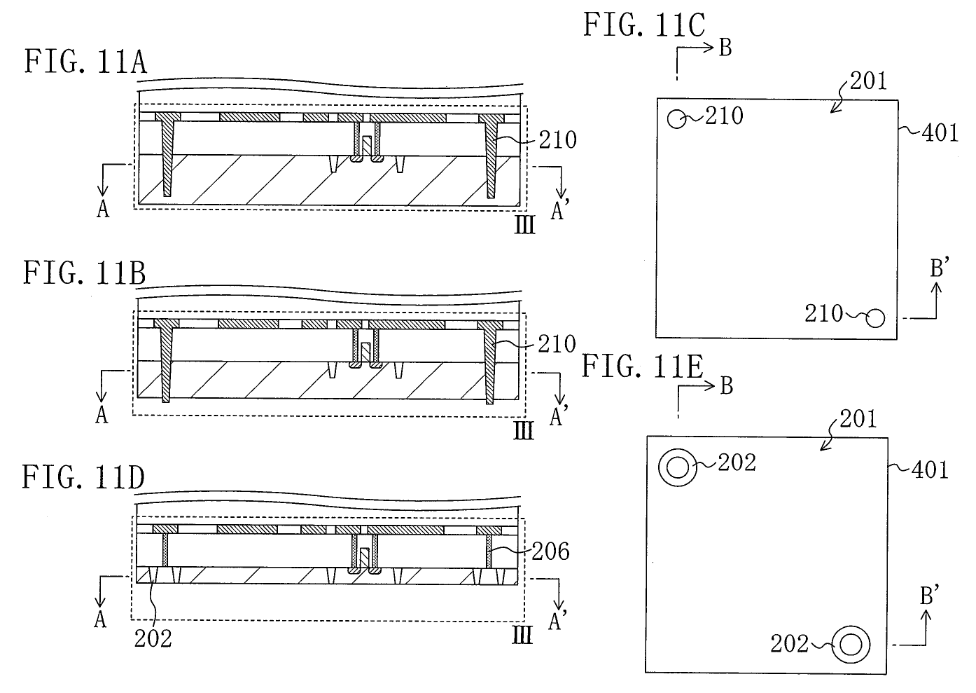

Next, a variation in the area III of FIG. 10 will be described with reference to FIGS. 11A-11C.

In FIG. 11A, the through via 210 is formed only at a position necessary for the alignment. If it is formed only at a position necessary for the alignment (near the peripheral portion of the chip area) without forming it other than at a position necessary for the alignment, as shown in FIG. 10, there is a cost advantage.

FIG. 11B shows an example where the reverse surface of the second wafer Wf2 is polished so that the second wafer Wf2 on which the through via bottom is exposed. In order to stack together many semiconductor substrates, it is preferred that the through via 210 is exposed.

FIG. 11C is a diagram showing positions necessary for the alignment (near the peripheral portion of the chip area 401) in the cross-sectional view taken along line A-A′ of FIGS. 11A and 11B. It can also be said that the cross-sectional view taken along line B-B′ of FIG. 11C corresponds to FIGS. 11A and 11B. It is preferred that the through vias 210 are formed at positions necessary for the alignment (near the peripheral portion of the chip area 401) as shown in FIG. 11C, and it is preferred that they are located opposite to each other with respect to the center of the chip area 401.

In FIG. 11D, the through via is not formed in the second wafer Wf2 and the plug 206 is formed at a position necessary for the alignment (near the peripheral portion of the chip area 401), with the device isolation 202 formed in the semiconductor substrate 201 so as to surround the position of the lower end of the plug 206. In this way, the interconnect 122 of the uppermost layer of the first wafer Wf1 can be electrically connected to the semiconductor substrate region connected to the lower end of the plug 206 through the interconnects 119, 116, 113, 222, 219, 216 and 213, the vias 121, 118, 115, 221, 218 and 215, the through via 110 and the plug 206. It is preferred to polish the reverse surface of the second wafer Wf2 until the bottom surface of the device isolation is exposed as shown in FIG. 11D, in which case it is possible to reduce the leakage of the current in the substrate plane direction.

FIG. 11E is a diagram showing positions necessary for the alignment (near the peripheral portion of the chip area 401) in the cross-sectional view taken along plane A-A′ of FIG. 11D. It can also be said that the cross-sectional view taken along plane B-B′ of FIG. 11E corresponds to FIG. 11D. It is preferred that the plugs 206 whose bottom surfaces are surrounded by the device isolations 202 are formed at positions necessary for the alignment (near the peripheral portion of the chip area 401) as shown in FIG. 11E, and it is preferred that they are located opposite to each other with respect to the center of the chip area 401.

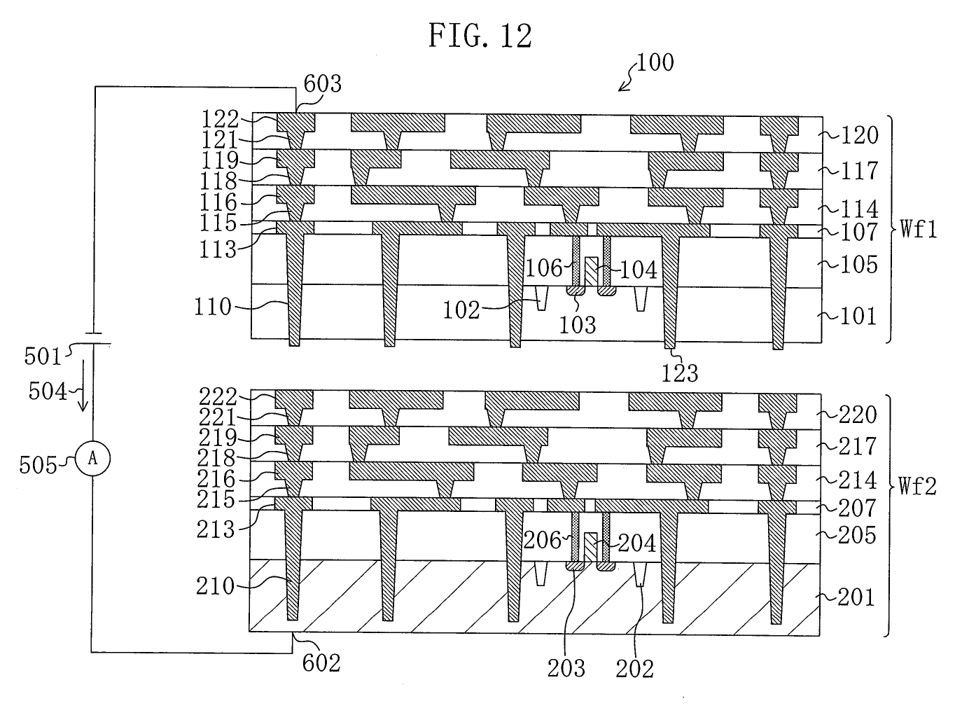

Next, the step of aligning the wafers with each other will be described. FIG. 12 is a diagram illustrating the alignment method of the present embodiment.

First, as with the first embodiment (FIGS. 8 and 9), the first wafer Wf1 is placed on the second wafer Wf2, and is aligned therewith to a certain degree by an optical method. Then, opposing terminals (not shown) of the power supply 501 are connected respectively to a connection pad 603 and a semiconductor substrate region 602 at the lower end of the through via 210, as shown in FIG. 12 (FIG. 12 shows the electrical connection of the power supply 501).

Then, the power supply 501 is turned on to apply a voltage, thereby allowing the current 504 to flow. The current 504 flows when the through via 110, which is connected to the connection pad 603 of the upper first wafer Wf1, is connected to the interconnect 222 of the uppermost layer, which is connected to the lower layer connection region (semiconductor substrate region) 602 of the lower second wafer Wf2 where the through via is formed. Then, the current value of the current 504 can be monitored through the ammeter 505.

Now, if the upper first wafer Wf1 and the lower second wafer Wf2 are not connected together, no current flows. When the through via 110 of the upper first wafer Wf1 lies over the interconnect 222 of the uppermost layer of the lower second wafer Wf2 but is not completely connected thereto, the resistance increases and therefore the current value decreases. Moreover, the current value is maximized when there is a complete connection.

In view of this, the upper first wafer Wf1 is translated or rotated by small amounts with respect to the principal surface of the lower second wafer Wf2 while monitoring the current value. Then, a position across the range of movement at which the current value is maximized is determined as the optimal position.

As in the first embodiment, the wafers can be attached together while directly observing the optimal position at which the misalignment is minimized, and it is therefore possible to perform a more accurate and appropriate alignment as compared with the background art which is an indirect alignment. Therefore, the yield of the electronic device manufacture is improved. Such a method is not limited to an alignment between wafers, but may also be compatible with an alignment between chips, an alignment of a chip with a wafer, etc.

Note that the first embodiment and the second embodiment illustrated examples where the first wafer Wf1 and the second wafer Wf2, each having a semiconductor substrate with MOS elements, the interconnect structure, etc., provided thereon, are bonded together, to manufacture a semiconductor apparatus as an electronic device. However, the present invention is not limited thereto. For example, even where an insulating substrate having a conductive film is used, the present invention can be applied with no problems to the conductive film. Moreover, the present invention can also be applied to such a case where a structure having the through vias 110 is aligned with and mounted on a printed circuit board.

### Third Embodiment

Next, an electronic device according to a third embodiment of the present disclosure and a method for manufacturing the same will be described.

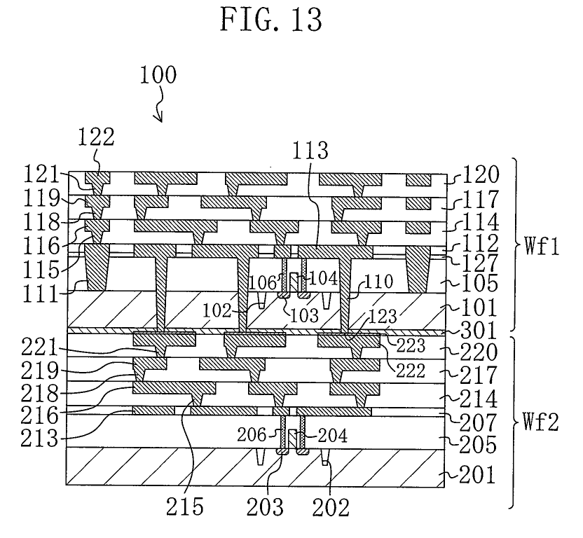

FIG. 13 shows a schematic cross-sectional view of a main part of an example electronic device 100 of the present embodiment. The electronic device 100 includes a first wafer Wf1, and a second wafer Wf2 on which the first wafer Wf1 is mounted. They are stacked together with the first wafer Wf1 being on the upper side and the second wafer Wf2 on the lower side, and are bonded together by an adhesive 301. In a predetermined area, the first wafer Wf1 and the second wafer Wf2 are electrically connected together. More specifically, there is provided a through via 110 running through a semiconductor substrate 101 of the first wafer Wf1 in the predetermined area, and the first wafer Wf1 and the second wafer Wf2 are electrically connected together via the through via 110. Moreover, an enclosure interconnect 111 is provided on the first wafer Wf1 so as to surround the through via 110.

Note that it is assumed that the figures of the embodiments each show one chip area of the wafer. The chip area can be assumed as a predetermined area. A chip area is an area to be an individual chip when the wafer is divided, and a plurality of MOS elements, etc., are formed on the semiconductor substrate 101 in each chip area.

The more detailed structure and formation method of the first wafer Wf1 and the second wafer Wf2 will now be described.

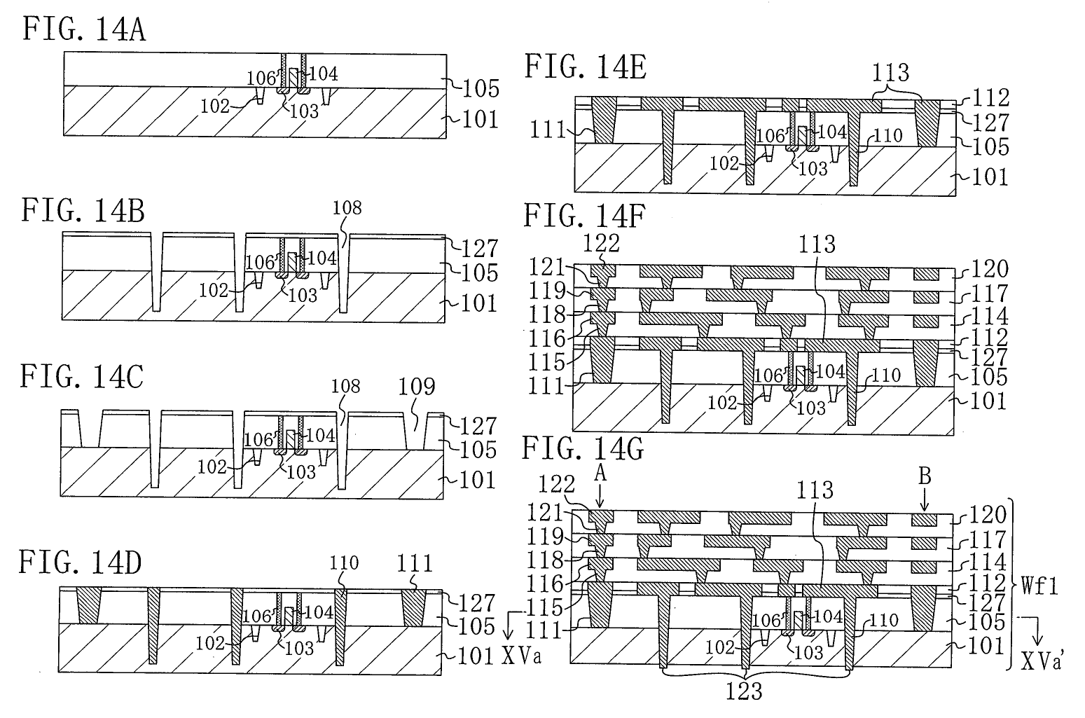

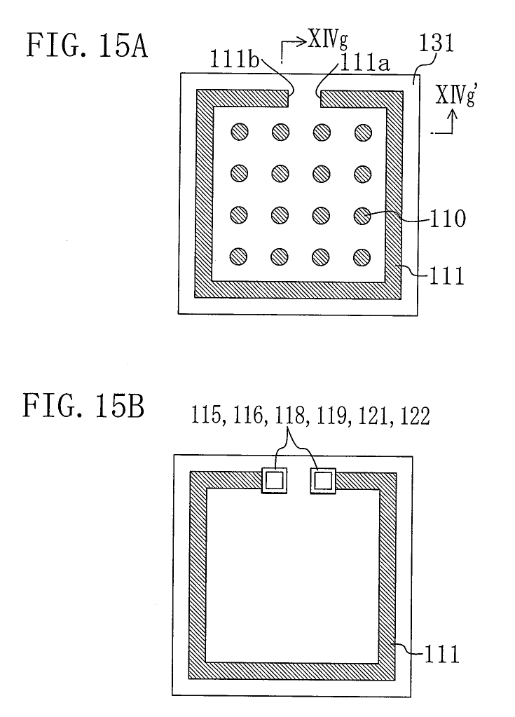

FIGS. 14A-14G are schematic cross-sectional views illustrating the structure and formation method of the first wafer Wf1 located in the upper portion of the electronic device 100. FIGS. 15A and 15B are plan views of the first wafer Wf1. FIG. 15A shows a cross section taken along line XVa-XVa′ of FIG. 14G, and FIG. 14G shows a cross section taken along line XIVg-XIVg′ of FIG. 15A. FIGS. 14A-14F show steps for forming the structure of FIG. 14G. The content of FIGS. 15A and 15B will be further described later.

In order to form the first wafer Wf1, the step of FIG. 14A is first performed. Here, there is provided the semiconductor substrate 101, which is a thin plate having a generally circular planar shape, for example. The semiconductor substrate 101 is a substrate made of an n-type or p-type single crystal silicon, for example.

A device isolation 102 is formed in the semiconductor substrate 101. This is formed by forming a groove on the upper surface of the semiconductor substrate 101 by a lithography method and a dry etching method, and filling the groove with a silicon oxide film (SiO₂) by a chemical vapor deposition (CVD) method, for example.

Then, a metal oxide semiconductor (MOS) element, for example, is formed in an active region of the semiconductor substrate 101 surrounded by the device isolation 102. The 103 element includes semiconductor regions 104 for the source and drain, a gate electrode 104, etc.

Now, the semiconductor region 103 is formed by adding a predetermined impurity (phosphorus (P) or arsenic (As), for example, for an n-channel type, and boron (B), for example, for a p-channel type) to the semiconductor substrate 101. The gate electrode 104 is formed as an electrode made of polysilicon on the semiconductor substrate 101 with a gate insulating film made of a silicon oxide film (SiO₂), for example, interposed therebetween.

Then, an insulating film 105 of a silicon oxide film, or the like, for example, is deposited so as to cover the semiconductor substrate 101. Then, an excess of the silicon oxide film deposited on the gate electrode 104 is removed by a chemical mechanical polishing (CMP), thereby flattening the structure. Then, a plug 106, which is to be connected to the semiconductor region 103 and the gate electrode 104 and electrically connected to interconnects to be formed in a subsequent step, is formed so as to be buried in the insulating film 105 (note however that the plug to be connected to the gate electrode 104 is not shown). The plug 106 is formed by a metal such as tungsten (W), aluminum (Al), or copper (Cu), for example.

Then, the step of FIG. 14B is performed. First, a liner film 127 is deposited across the entire surface so as to cover the plug 106 and the insulating film 105. This is, for example, formed as a silicon nitride film (SiN) having a thickness of about 30 nm by a CVD method. A silicon oxide film may be used instead of a silicon nitride film.

Then, through via holes 108 are formed by using a lithography method and a dry etching method. They are formed to such a depth as to run through the liner film 127 and the insulating film 105 and to further cut into about 1/7 to ⅛, for example, of the semiconductor substrate 101. For example, if the thickness of the semiconductor substrate 101 is 750 μm, the depth is 100 μm.

Then, the step shown in FIG. 14C is performed. First, the through via hole 108 is filled with a resist (not shown), and then a portion of the resist overflowing onto the liner film 127 is removed by a dry etching method, a CMP method, etc., thereby forming a resist plug (not shown) in the through via hole 108.

Then, an enclosure interconnect groove 109 is formed in the liner film 127 and the insulating film 105 by a lithography method and a dry etching method in a region where the resist plug is formed (which may be regarded in FIG. 14C as a region where the through via hole 108 is formed). The planar arrangement of the through via hole 108, the enclosure interconnect groove 109, etc., will be further described later with reference to FIG. 15A.

Then, the resist plug buried in the through via hole 108 is removed by a dry etching method and a washing process, for example.

Then, the step of FIG. 14D is performed. First, a barrier film made of tantalum (Ta)/tantalum nitride (TaN) and a copper (Cu) film are deposited in this order by using a sputtering method and a plating method so as to fill the through via hole 108 and the enclosure interconnect groove 109 and cover the liner film 127. Then, portions of the barrier film and the copper film overflowing onto the liner film 127 are removed by using a CMP method, thereby forming the through via 110 and the enclosure interconnect 111 so as to fill the through via hole 108 and the enclosure interconnect groove 109, respectively.

Note that while a layered film of a Ta film and a TaN film is used here as the barrier film, the barrier film may be made of only one of a Ta film and a TaN film. While copper is used as a material of a conductive film that fills the through via hole 108 and the enclosure interconnect groove 109, it may alternatively be silver (Ag), aluminum (Al), or an alloy thereof, etc.

It is preferred that an insulative film is formed, before the barrier film is formed, on the side wall of the through via hole 108. Alternatively, the through vias 110 may be surrounded by an insulating substance, instead of forming the insulative film.

Then, the step of FIG. 14E is performed. Here, the interconnect 113 is formed. For this, first, an insulating film 112 made of a silicon oxide film having a thickness of 200 nm is deposited by a CVD method, for example, so as to cover the through via 110, the enclosure interconnect 111 and the liner film 127. Then, a plurality of interconnect grooves are formed spaced apart from one another by a lithography method and a dry etching method so as to run through both the insulating film 112 and the liner film 127.

Then, a barrier film made of tantalum (Ta)/tantalum nitride (TaN) and a copper (Cu) film are deposited in this order by a sputtering method and a plating method so as to fill the interconnect grooves and cover the insulating film 112.

Then, unnecessary portions of the barrier film and the copper film overflowing onto the insulating film 112 are removed by using a CMP method, thereby forming the interconnects 113 made of the barrier film and the copper film and filling the interconnect grooves. Note that by setting the positions of the interconnect grooves, the interconnects 113 may be provided so as to be connected to the top of the through via 110, the enclosure interconnect 111, etc., as necessary.

Again, the barrier film is not limited to a layered structure of Ta film/TaN film, and it may be solely a Ta film, a TaN film, or the like. A film made of silver, aluminum or an alloy thereof may be used instead of the copper film.

Then, the step of FIG. 14F is performed. Here, a plurality of insulating films 114, 117 and 120 layered together, and interconnect structures (vias 115, 118 and 121 and interconnects 116, 119 and 122) to be buried therein are formed. Note that as opposed to the enclosure interconnect 111, the interconnects 116, 119 and 122 do not need to have such a planar shape as to surround the through via 110.

First, the insulating film 114 made of a silicon oxide film having a thickness of 400 nm is deposited by a CVD method, for example, so as to cover the insulating film 112 including the interconnects 113. Then, a plurality of via holes and interconnect grooves connected to the top of the plurality of via holes are formed in the insulating film 114 by a lithography method and a dry etching method.

Then, a barrier film made of tantalum (Ta)/tantalum nitride (TaN) and a copper (Cu) film are deposited in this order by a sputtering method and a plating method so as to fill the via holes and the interconnect grooves and cover the insulating film 114.

Then, unnecessary portions of the barrier film and the copper film overflowing onto the insulating film 114 are removed by using a CMP method, thereby forming the vias 115 and the interconnects 116 having a structure in which the via holes and the interconnect grooves are filled by the barrier film and the copper film. Note that the via 115 that connects to a desired position of the interconnect 113 can be formed by setting the position of the via hole as necessary.

Moreover, similar steps are repeated to form the insulating film 117 formed on the insulating film 114 and the via 118 and the interconnect 119 buried therein, and an insulating film 120 formed on the insulating film 117 and the via 121 and the interconnect 122 buried therein, thus forming a multi-layer interconnect structure. While the total number of interconnect layers is four, this is an example, and the number is not limited to this.

Note that the insulating films 114, 117 and 120 each have a single-layer structure of a silicon oxide film in the present embodiment. However, it may alternatively be a single-layer structure of another material, or a layered film of silicon oxide film/silicon nitride film, etc. The barrier film is not limited to a layered structure of Ta film/TaN film, and may be solely a Ta film, a TaN film, or the like. Moreover, a film of silver, aluminum or an alloy thereof may be used instead of a copper film.

Then, the step of FIG. 14G is performed. Here, a thinning process is performed on the semiconductor substrate 101 from the reverse surface thereof so that the lower end portion of the through via 110 is exposed as a through via bottom 123 on the reverse surface side of the semiconductor substrate 101.

As the thinning process, for example, the reverse surface of the semiconductor substrate 101 is first polished to a desired thickness, and then a polish process having both mechanical and chemical aspects such as a CMP method is performed. At this point, the through via bottom 123 is not exposed. Then, the reverse surface of the semiconductor substrate 101 is etched by a wet etching method so that the through via bottom 123 is exposed.

As another example of the thinning process, a CMP method and a wet etching method may be used without performing the polish. Moreover, the thinning process may be performed by only a CMP method or by only a wet etching method.

The first wafer Wf1 located in the upper portion of the electronic device 100 is formed as described above.

Next, the planar arrangement of the through via 110 and the enclosure interconnect 111 (and also the through via hole 108 and the enclosure interconnect groove 109) will be described.

FIG. 15A shows, as a cross section taken along line XVa-XVa′ of FIG. 14G, an example of the planar shape of the enclosure interconnect 111 and the through via 110. Note however that the gate electrode 104, the plug 106, etc., are not shown. FIG. 15A shows one chip area 131.

In FIG. 15A, a plurality of through vias 110 are placed in the chip area 131, and the enclosure interconnect 111 is placed so as to surround a portion of the chip area 131 (so as to surround all of the plurality of through vias 110). Note that the enclosure interconnect 111 has such a shape that it makes a substantially complete round continuously to form a ring, but it is formed so as to prevent the opposite ends thereof (end portions 111a and 111b) from contacting each other.

FIG. 15B is a plan view illustrating the path for allowing a current to flow from the upper surface of the first wafer Wf1 to the enclosure interconnect 111, seen through the insulating films 114, 117 and 120, etc. As illustrated here, the interconnects 113, 116, 119 and 122 and the vias 115, 118 and 121 form a layered structure above each of the end portions 111a and 111b of the enclosure interconnect 111, thus ensuring an electrical path to the top of the insulating film 120 of the uppermost layer. The interconnect 122 of the uppermost layer functions as a terminal pad for allowing a current to flow through the enclosure interconnect 111.

Now, in order to minimize the path, it is preferred that the layered structure is provided so as to extend directly above the end portions 111a and 111b as shown in FIG. 15B.

Other elements are not shown in FIG. 15B. Particularly, the interconnects 113, 116, 119 and 122 and the vias 115, 118 and 121 may be arranged in any pattern above the enclosure interconnect 111, excluding above the end portions 111a and 111b, and above the region within the enclosure interconnect 111.

Note that in FIG. 14G, the portion A shows how an electrical path is formed above the end portion 111b of the enclosure interconnect 111, and the portion B shows portions other than the end portion of the enclosure interconnect 111.

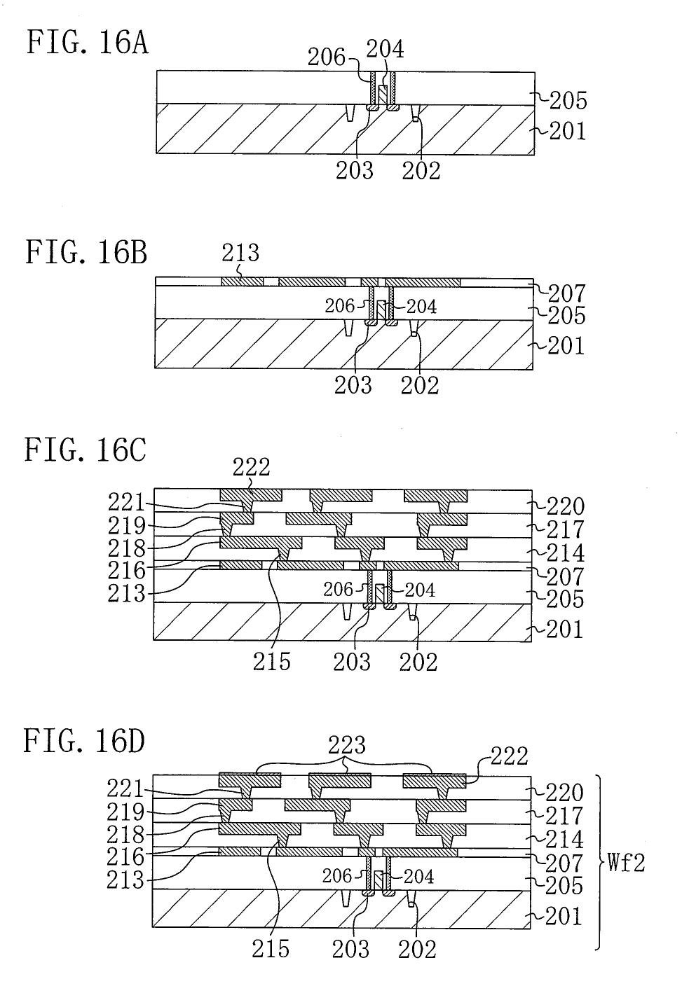

Next, FIGS. 16A-16D are schematic cross-sectional views illustrating the structure and formation method of the second wafer Wf2 located in the lower portion of the electronic device 100.

First, a structure shown in FIG. 16A is formed. This is similar to the structure shown in FIG. 14A for the first wafer Wf1, the only difference being the reference numerals. That is, an active region is defined by a device isolation 202 on a semiconductor substrate 201, and a MOS element including a semiconductor region 203, a gate insulating film (not shown) and a gate electrode 204 is formed in the active region. An insulating film 205 is formed so as to cover the semiconductor substrate 101 including the MOS element, and a plug 206 is formed so as to reach the semiconductor region 203, etc., through the insulating film 205. These can be formed in a similar manner to that described above for the first wafer Wf1. Note however that the second wafer Wf2 does not need to have a similar structure to that of the first wafer Wf1, but may have a different structure.

Then, the step shown in FIG. 16B is performed. First, an insulating film 207 of a silicon oxide film having a thickness of 200 nm is deposited by a CVD method, for example, so as to cover the plug 206 and the insulating film 205. Then, a plurality of interconnect grooves are formed on the insulating film 207 spaced apart from one another by a lithography method and a dry etching method.

Then, a barrier film made of tantalum (Ta)/tantalum nitride (TaN) and a copper (Cu) film are deposited in this order by a sputtering method and a plating method so as to fill the interconnect grooves and cover the insulating film 207.

Then, unnecessary portions of the barrier film and the copper film overflowing onto the insulating film 207 are removed by using a CMP method, thereby forming the interconnects 213 made of the barrier film and the copper film and filling the interconnect grooves. Note that by setting the positions of the interconnect grooves, the interconnect 213 can be placed at any position so that, for example, it is connected to the top of the plug 206.

Again, the barrier film is not limited to a layered structure of Ta film/TaN film, and it may be solely a Ta film, a TaN film, or the like. A film made of silver, aluminum or an alloy thereof may be used instead of the copper film.

Then, the step shown in FIG. 16C is performed. Here, a plurality of insulating films 214, 217 and 220 layered together, and interconnect structures (vias 215, 218 and 221 and interconnects 216, 219 and 222) to be buried therein are formed.

These can be formed in a similar manner to that described above for the first wafer Wf1 with reference to FIG. 14F, for example. Note however that a different method may be used.

Since the interconnect 222 located in the uppermost layer needs to be connected to the through via bottom 123 in the first wafer Wf1, it is formed at a position appropriate therefor. The interconnects 216 and 219 in other layers and vias 215, 218 and 221 for connecting interconnects of different layers may be arranged in any manner.

Then, a cap film 223 is formed by an electroless plating method, or the like, on the surface of the interconnect 222 of the uppermost layer as shown in FIG. 16D. Now, a material having a ferromagnetic property is used for the cap film 223. For example, it may be a ferromagnetic metal, e.g., a simple substance of iron (Fe), cobalt (Co), nickel (Ni) or gadolinium (Gd), an alloy containing at least one of Fe, Co, Ni and Gd, a material containing at least one of oxides of Fe, Co, Ni and Gd, etc.

Note that in the present embodiment, the interconnect 222 of the uppermost layer has a structure in which the interconnect groove is filled with copper, silver, aluminum, an alloy thereof, or the like. In such a case, there is provided the cap film 223 made of a ferromagnetic material.

Alternatively, the interconnect 222 of the uppermost layer may be formed by filling the interconnect groove with the material (Fe, Co, Ni, Gd, etc.), which has been mentioned above as the material of the cap film 223. In such a case, the cap film 223 does not need to be formed.

The second wafer Wf2 located in the lower portion of the electronic device 100 is formed as described above.

Then, the first wafer Wf1 is aligned with and mounted on the second wafer Wf2, and the wafers are bonded together. The bonding step will now be described.

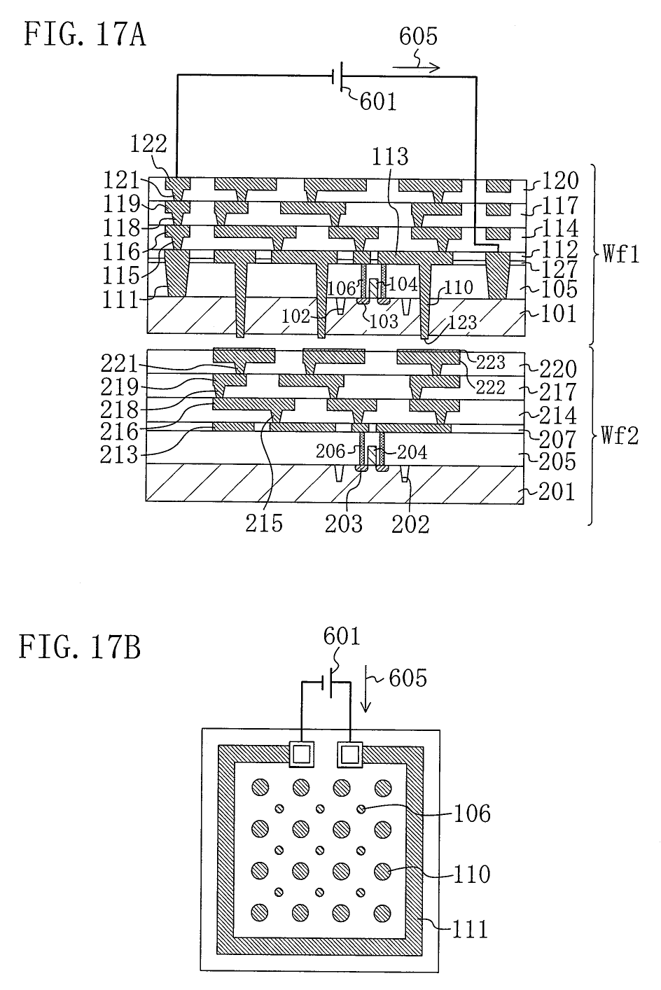

FIGS. 17A and 17B are a cross-sectional view and a plan view illustrating the alignment method for the step of bonding together the first wafer Wf1 and the second wafer Wf2.

First, the lower second wafer Wf2 is provided, and the upper first wafer Wf1 is placed thereon so that the reverse surface thereof faces the principal surface of the second wafer Wf2.

Then, the relative positions of the second wafer Wf2 and the first wafer Wf1 are aligned with each other. Specifically, the interconnect 222 (and the cap film 223) of the uppermost layer of the second wafer Wf2 is aligned with the corresponding through via bottom 123 on the reverse surface of the first wafer Wf1.

Moreover, the opposing surfaces of the wafers are brought closer to each other, and the interconnect 222 of the uppermost layer of the second wafer Wf2 is brought into contact with the through via bottom 123 of the first wafer Wf1 so as to electrically connect them together. Thus, the first wafer Wf1 and the second wafer Wf2 are electrically connected together.

Then, the insulative adhesive 301 is injected into the gap between the first wafer Wf1 and the second wafer Wf2 (see FIG. 13), thereby bonding together the first wafer Wf1 and the second wafer Wf2 and thus ensuring the mechanical strength.

After bonding together the first wafer Wf1 and the second wafer Wf2, the wafers are cut into chips, thereby obtaining individual chips (the electronic devices 100). An electronic device obtained as described above has a three-dimensional structure in which a plurality of (two here) chips stacked together. That is, semiconductor circuits, etc., provided on a plurality of chips are electrically connected together through the through vias, thereby forming a single semiconductor integrated circuit as a whole.

Now, the alignment between the first wafer Wf1 and the second wafer Wf2 will be further described.

An alignment to a certain degree is performed by using an optical alignment method, or the like. Then, as shown in FIGS. 17A and 17B, a power supply 601 is connected so as to allow a current to flow through the enclosure interconnect 111 provided on the first wafer Wf1 through interconnect structures formed above the end portions 111a and 111b of the enclosure interconnect 111. For this, opposing terminals (not shown) of the power supply 601 are each connected to the interconnect 122 of the uppermost layer (this portion functions as the terminal pad). Note that FIG. 17A schematically shows the electrical connection.

Then, the power supply 601 is turned on to apply a voltage, thereby allowing a current 605 to flow through the enclosure interconnect 111. The enclosure interconnect 111 is arranged so as to make a substantially complete round around the area in which electrical connections are made between the wafers, with the through via 110 placed within the enclosure interconnect 111. Thus, when a current flows through the enclosure interconnect 111, a magnetic field is generated, and the through via 110 becomes a magnet with a magnetic force.

When the first wafer Wf1 and the second wafer Wf2 are brought close to each other in this state, the cap film 223 provided on the interconnect 222 of the uppermost layer of the second wafer Wf2 is drawn toward the through via bottom 123 of the magnetized through via 110 in the first wafer Wf1.

As a result, the second wafer Wf2 is drawn toward the first wafer Wf1, and displaced in the direction vertical to the second wafer Wf2. They are translated or rotated by small amounts while maintaining the parallel position between the principal surface of the second wafer Wf2 and the reverse surface of the first wafer Wf1 and while observing such displacement. It is assumed that the wafers are most accurately aligned with each other (with minimum misalignment) at such a position that the displacement is maximized, and therefore such a position is determined as the optimal position.

With such an alignment method, the wafers can be attached together while directly observing the optimal position at which the misalignment is minimized, and it is therefore possible to perform a more accurate and appropriate alignment as compared with the background art which is an indirect alignment. Therefore, the yield of the electronic device manufacture is improved. Such a method is not limited to an alignment between wafers, but may also be compatible with an alignment between chips, an alignment of a chip with a wafer, etc.

(Variations)

Next, various variations of the third embodiment will be described.

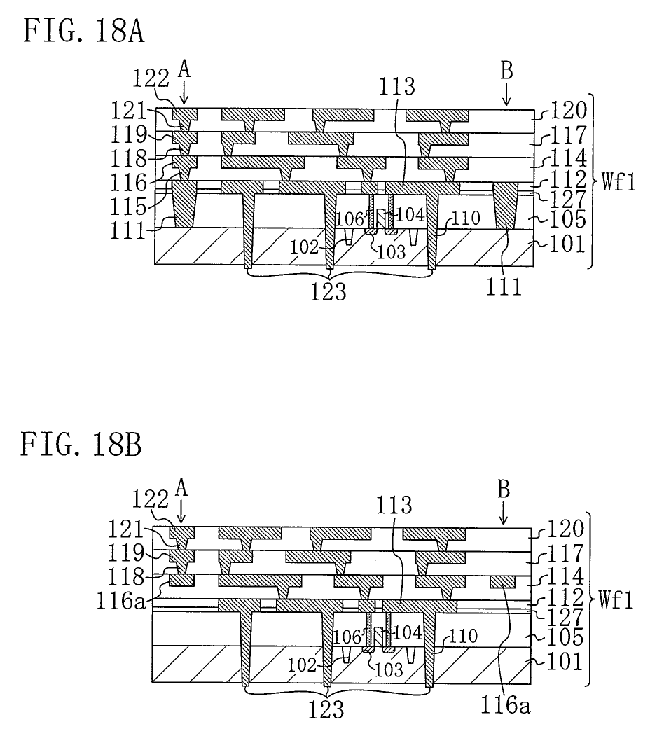

FIG. 18A is a cross-sectional view showing a structure replacing the first wafer Wf1 shown in FIG. 14G. In FIG. 14G, the interconnects 116, 119 and 122, which are not connected to the enclosure interconnect 111, are formed in the area above a portion of the enclosure interconnect 111 other than the end portions 111a and 111b (the area denoted as B).

In contrast, FIG. 18A shows a case where the interconnects 116, 119 and 122 are not formed above the portion of the enclosure interconnect 111 other than the end portions 111a and 111b. For the enclosure interconnect 111, it is only necessary that a path for electrical connection is formed for the end portions 111a and 111b, and there is no limitation on the structure for areas above the other portions, and it may be as shown in FIG. 18A. FIG. 18A shows that in the area denoted as A, the interconnects 116, 119 and 122, which are not enclosure interconnects, are formed, thereby forming a path for electrical connection. However, an electrical path may be formed only by vias.

Next, FIG. 18B shows an example where an interconnect 116a is formed, instead of the enclosure interconnect 111, so as to surround the area where the through vias 110 are formed. Now, the shape of the interconnect 116a as viewed from above may be assumed to be similar to that of the enclosure interconnect 111 in FIGS. 15A and 15B. The opposite ends of the interconnect 116a are not in contact with each other, and an electrical path for allowing a current to flow through the interconnect 116a is formed by vias and interconnects above each of the opposite ends.

The enclosure interconnect 111 shown in FIG. 14G, etc., surrounds the through via 110 in the same layer. In contrast, the interconnect 116a of FIG. 18B, which lies in a higher layer than the through via 110, surrounds the through via 110 as viewed from above. Also in such a case, it is possible to allow a current to flow through the interconnect 116a to thereby generate a magnetic field, and to provide the through via 110 with a magnetic force. Therefore, the alignment method described above can be carried out also in this case.

In FIG. 18B, in the portion denoted as A, the interconnects 119 and 122, which are not enclosure interconnects, are formed, thereby forming a path for allowing a current to flow through the interconnect 116a. However, such a path may be formed only by vias. Although FIG. 18B shows a case where the interconnects 119 and 122 are not formed in the portion denoted as B, one of the interconnects 119 and 122 may be formed in this portion.

In addition to the enclosure interconnect 111 shown in FIG. 14G, etc., the configuration may include an interconnect that surrounds the through via 110 as viewed from above, as does the interconnect 116a shown in FIG. 18B. Note however that if the enclosure interconnect 111 is provided, the interconnects 116, 119 and 122, etc., of FIG. 14G preferably do not have a planar shape that surrounds the through via 110.

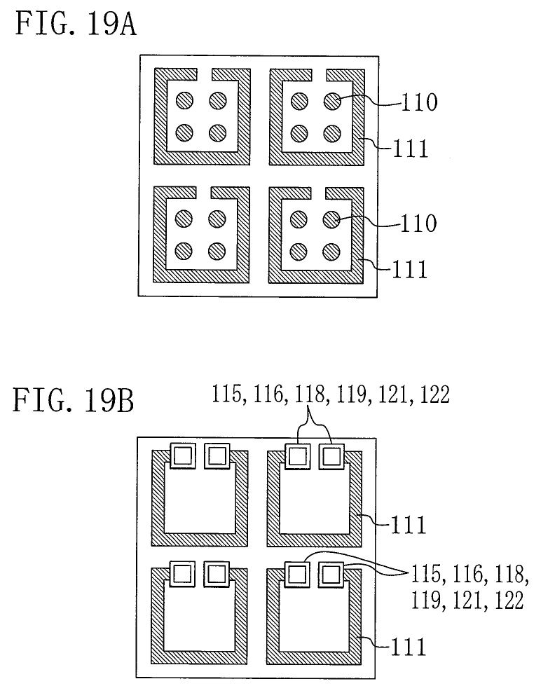

In the third embodiment, only one enclosure interconnect 111 is provided in one chip area as shown in FIGS. 15A and 15B. However, the present invention is not limited to this, and may employ a configuration shown in FIGS. 19A and 19B. That is, a plurality of enclosure interconnects 111 may be provided, with the through via 110 placed within each of the enclosure interconnects 111. In such a case, it may be assumed that a plurality of regions are provided for alignment and electrical connection, each region including one enclosure interconnect 111 on the first wafer Wf1 and the through via 110 within the enclosure interconnect 111, and the interconnect 222 (and the cap film 223) of the second wafer Wf2 corresponding to the through via 110. By performing the alignment for the plurality of regions, it is possible to perform an alignment of a better precision.

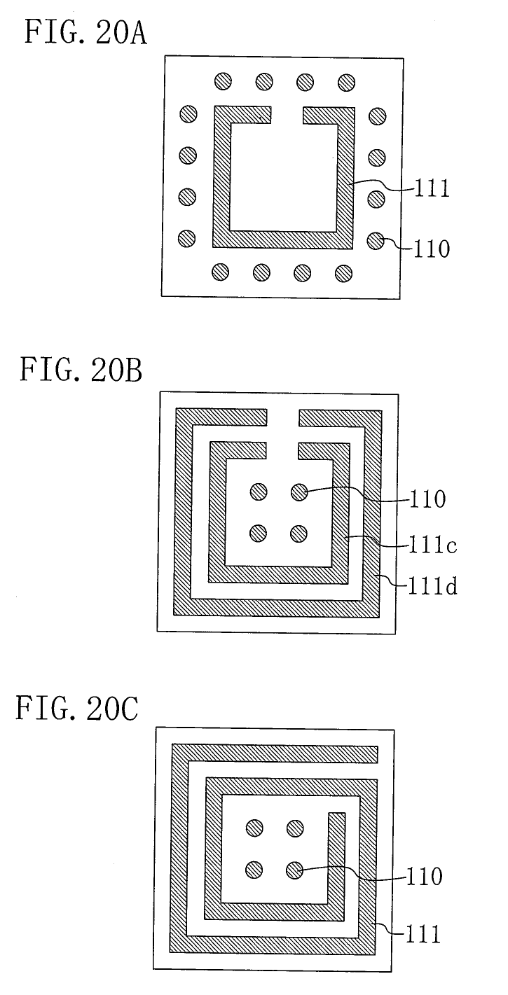

The third embodiment illustrated an example where the through via 110 is placed inside the enclosure interconnect 111. However, the through vias 110 may be arranged outside the enclosure interconnect 111 as shown in FIG. 20A.

For providing the through via 110 with a magnetic force, it is advantageous that the through via 110 is placed within the enclosure interconnect 111. However, a magnetic force can be given to the through vias 110 placed outside the enclosure interconnect 111, and it is possible that the through vias 110 are placed outside due to the structural limitations of the electronic device, etc. This is advantageous in terms of the degree of freedom in the structure of the electronic device.

A plurality of enclosure interconnects 111c and 111d may be provided so as to surround the area where the through vias 110 are placed in multiple rows as shown in FIG. 20B. In this way, it is advantageous in magnetizing the through via 110.

Moreover, the enclosure interconnect 111 may be formed in a spiral pattern so as to surround the through via 110 as shown in FIG. 20C. This is also advantageous in magnetizing the through via 110.

Note that the various variations described above may be combined with one another. For example, it is possible to employ any of configurations such as one where the interconnects 116a are provided in a plurality of rows as shown in FIG. 20B, one where the through vias 110 are placed both inside and outside the enclosure interconnect 111, and one with a plurality of such regions as shown in FIGS. 20A-20C.

### Fourth Embodiment

Next, an electronic device according to a fourth embodiment of the present disclosure and a method for manufacturing the same will be described.

The electronic device of the present embodiment has a structure in which two wafers are stacked together, as does the electronic device 100 of the third embodiment. The second wafer Wf2 to be on the lower side has the same structure as that of the second wafer Wf2 of the third embodiment shown in FIG. 13, and can be manufactured as described above in the third embodiment.

In contrast, the structure and formation method of a first wafer Wf1′ of the present embodiment to be mounted on the second wafer Wf2 will now be described.

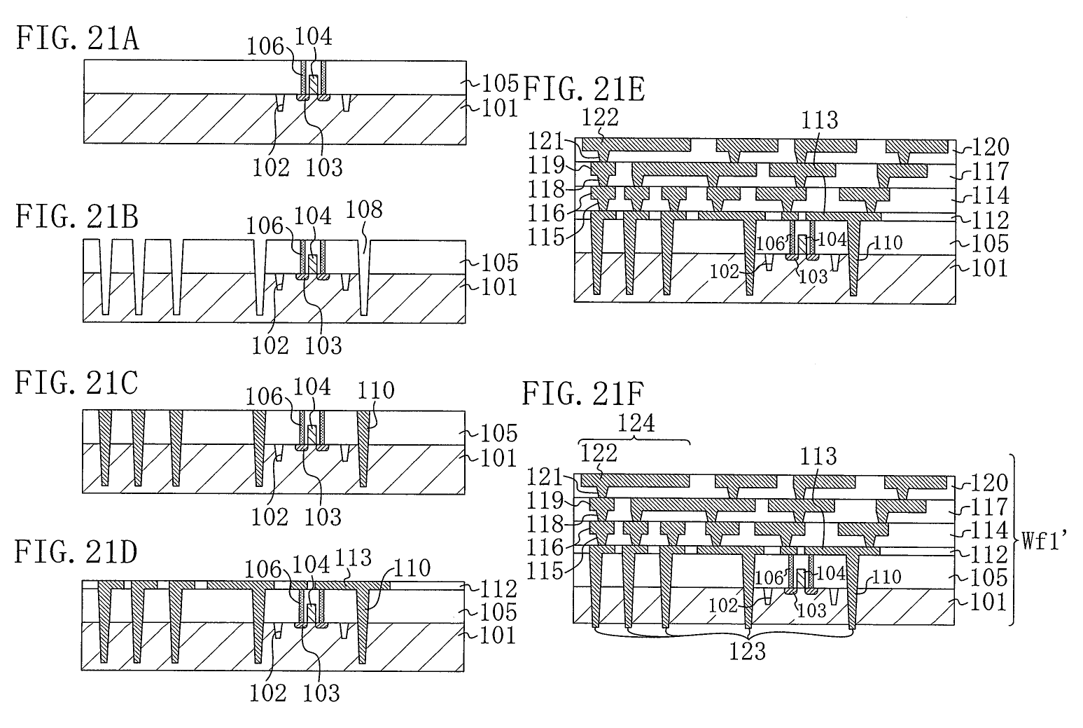

FIGS. 21A-21D are schematic cross-sectional views illustrating the structure and formation method of the first wafer Wf1′ of the present embodiment.

The structure shown in FIG. 21A is similar to the structure shown in FIG. 14A as the formation method of the first wafer Wf1 of the third embodiment. Therefore, the semiconductor substrate 101, the device isolation 102, the semiconductor region 103, the gate electrode 104, the insulating film 105 and the plug 106 may be formed as already described above.

Then, the step of FIG. 21B is performed. Here, the through via hole 108 is formed by using a lithography method and a dry etching method. This is formed to such a depth as to run through the insulating film 105 and to further cut into about 1/7 to ⅛, for example, of the semiconductor substrate 101. If the thickness of the semiconductor substrate 101 is 750 μm, the depth is 100 μm.

Then, the step of FIG. 21C is performed. First, a barrier film made of tantalum (Ta)/tantalum nitride (TaN) and a copper (Cu) film are deposited in this order by using a sputtering method and a plating method so as to fill the through via hole 108 and cover the insulating film 105. Then, portions of the barrier film and the copper film overflowing onto the insulating film 105 are removed by using a CMP method, thereby forming the through via 110 so as to fill the through via hole 108.

The barrier film is not limited to a layered structure of Ta film/TaN film, and may be solely a Ta film, a TaN film, or the like. Moreover, a film of silver, aluminum or an alloy thereof may be used instead of a copper film.

It is preferred that an insulative film is formed, before the barrier film is formed, on the side wall of the through via hole 108. Alternatively, the through vias 110 may be surrounded by an insulating substance, instead of forming the insulative film.

Then, the step of FIG. 21D is performed. Here, the interconnect 113 is formed. For this, first, an insulating film 112 made of a silicon oxide film having a thickness of 200 nm is deposited by a CVD method, for example, so as to cover the through via 110 and the insulating film 105.

Then, a plurality of interconnect grooves are formed spaced apart from one another by a lithography method and a dry etching method so as to run through both the insulating film 112.

Then, a barrier film made of tantalum (Ta)/tantalum nitride (TaN) and a copper (Cu) film are deposited in this order by a sputtering method and a plating method so as to fill the interconnect grooves and cover the insulating film 112.

Then, unnecessary portions of the barrier film and the copper film overflowing onto the insulating film 112 are removed by using a CMP method, thereby forming the interconnects 113 made of the barrier film and the copper film and filling the interconnect grooves. Note that by setting the positions of the interconnect grooves, the interconnect 113 can be placed at any position so that, for example, it is connected to the top of the through via 110 or the top of the plug 106.

Again, the barrier film is not limited to a layered structure of Ta film/TaN film, and it may be solely a Ta film, a TaN film, or the like. A film made of silver, aluminum or an alloy thereof may be used instead of the copper film.

Then, the step shown in FIG. 21E is performed. Here, a plurality of insulating films 114, 117 and 120 layered together, and interconnect structures (vias 115, 118 and 121 and interconnects 116, 119 and 122) to be buried therein are formed.

The method for this is similar to the method described above in the third embodiment with reference to FIG. 14F.

Next, the step of FIG. 21F will be described. Here, a thinning process is performed on the semiconductor substrate 101 from the reverse surface thereof so that the lower end portion of the through via 110 is exposed as a through via bottom 123 on the reverse surface side of the semiconductor substrate 101. The method for this is similar to the method described above in the third embodiment with reference to FIG. 14G.

The first wafer Wf1′ to be on the upper side in the present embodiment is formed as described above.

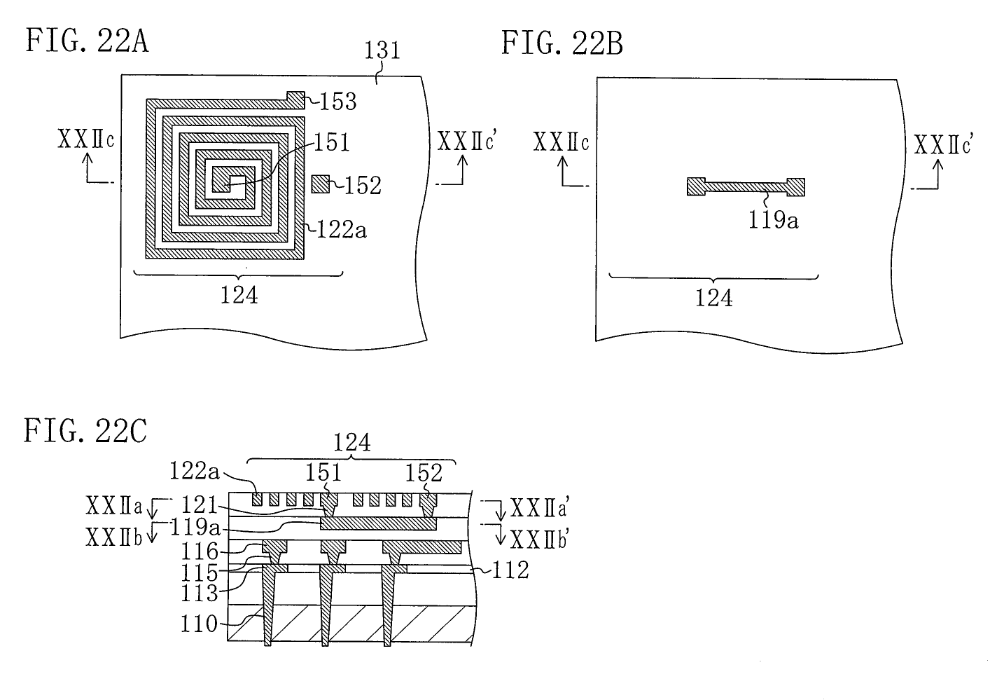

Now, an inductor 124 is formed by the interconnect 122 of the uppermost layer of the first wafer Wf1′. This will be described with reference to FIGS. 22A-22C.

FIG. 22C is a diagram showing in detail on an enlarged scale an area near the inductor 124 of FIG. 21F. FIGS. 22A and 22B are diagrams showing the planar configuration of the area near the inductor 124, and represent the cross section taken along line XXIIa-XXIIa′ passing through the insulating film 120 in FIG. 22C and the cross section taken along line XXIIb-XXIIb′ passing through the insulating film 117 in FIG. 22C, respectively. The cross sections taken along line XXIIc-XXIIc′ of FIGS. 22A and 22B correspond to FIG. 22C.

As shown in FIG. 22A, in the chip area 131, the inductor 124 of a spiral pattern is formed by an interconnect 122a of the uppermost layer. The outer end portion of the interconnect 122a of the inductor 124 is provided with a connection pad 153 for making a connection with a measurement probe terminal during the alignment. The inner end portion is provided with a connection pad 151 for making a connection with an interconnect 119a of the lower layer shown in FIGS. 22B and 22C via the via 121. The interconnect 119a is electrically connected to a connection pad 152 provided outside the inductor 124.

Note that it is preferred that at least one through via 110 is placed under the inductor 124.

After the formation of the first wafer Wf1′ and the second wafer Wf2 is completed, the wafers are aligned and bonded together. Now, the process of placing the first wafer Wf1′ on the second wafer Wf2, the process of bringing the interconnect 222 of the uppermost layer of the second wafer Wf2 and the cap film 223 thereon and the through via bottom 123 of the first wafer Wf1′ into contact with each other for an electrical connection, and the process of further bonding together the wafers using an adhesive to thereby ensure a mechanical strength are similar to those of the third embodiment.

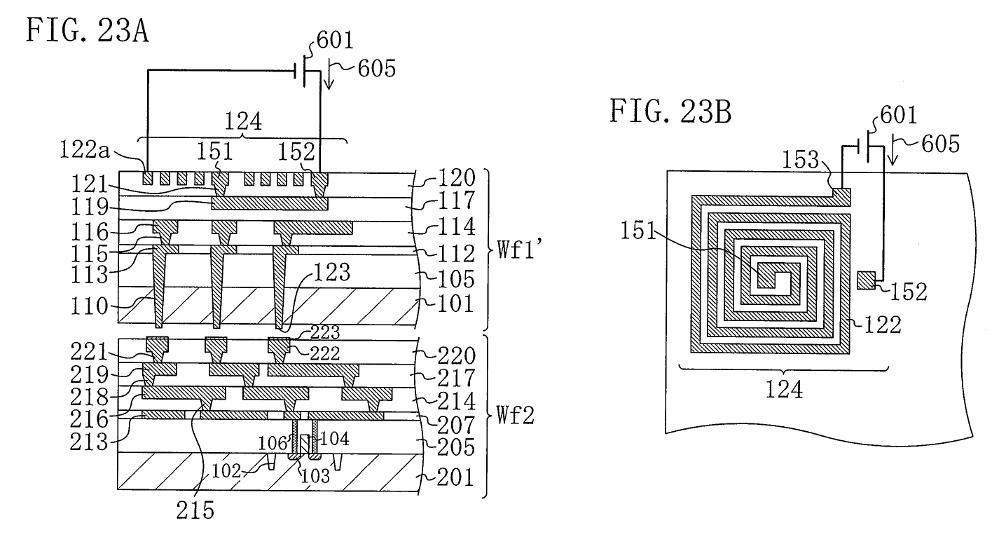

The step of aligning the wafers with each other will now be described. FIGS. 23A and 23B are diagrams illustrating the alignment method of the present embodiment.

First, as in the third embodiment (FIGS. 17A and 17B), the first wafer Wf1′ is placed on the second wafer Wf2, and is aligned therewith to a certain degree by an optical method. Then, as shown in FIGS. 23A and 23B, the power supply 601 is connected so as to allow a current to flow through the inductor 124. For this, the opposing terminals (not shown) of the power supply 601 are connected respectively to the connection pads 152 and 153 (FIGS. 23A and 23B show the electrical connection of the power supply 601).

Then, when the power supply 601 is turned on to apply a voltage, thereby allowing a current 605 to flow through the inductor 124, a magnetic field is generated. With the magnetic field, the through via 110 becomes a magnet with a magnetic force, thereby drawing the cap film 223 of the second wafer Wf2.

Thus, the second wafer Wf2 is drawn toward the first wafer Wf1′, and displaced in the direction vertical to the second wafer Wf2. They are translated or rotated by small amounts while maintaining the parallel position between the principal surface of the second wafer Wf2 and the reverse surface of the first wafer Wf1′ and while observing such displacement. The position at which the displacement is maximized is determined as the optimal position.

As in the third embodiment, the wafers can be attached together while directly observing the optimal position at which the misalignment is minimized, and it is therefore possible to perform a more accurate and appropriate alignment as compared with the background art which is an indirect alignment. Therefore, the yield of the electronic device manufacture is improved. Such a method is not limited to an alignment between wafers, but may also be compatible with an alignment between chips, an alignment of a chip with a wafer, etc.

(Variations)

Next, various variations of the fourth embodiment will be described.

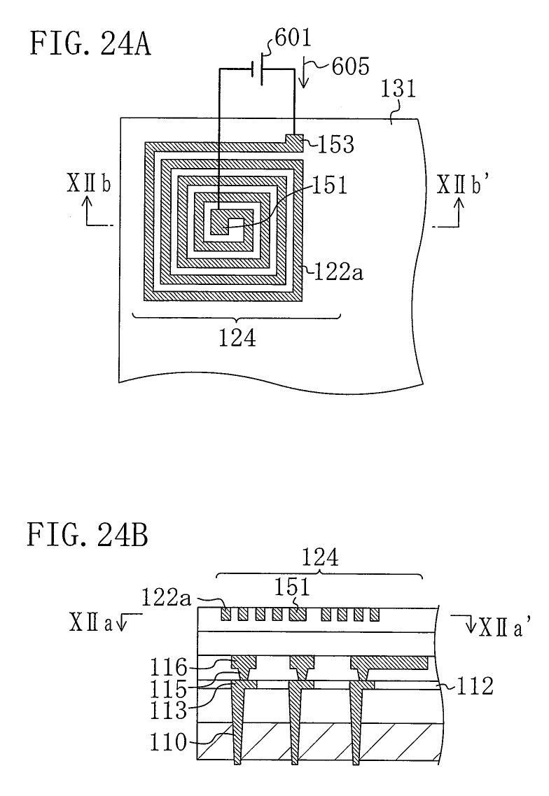

FIGS. 24A and 24B show a variation of the inductor 124. With the inductor 124 described above in the fourth embodiment with reference to FIGS. 22A-22C, the electrical path is extended from the connection pad 151 inside the inductor 124 to the connection pad 152 via the interconnect 119a of the lower layer, etc. In contrast, in FIGS. 24A and 24B, the interconnect 119a, the connection pad 152, etc., are not provided.

In such a case, in the alignment step, the power supply 601 is connected to the connection pad 153 provided at the outer end portion of the inductor 124 and the connection pad 151 provided at the inner end portion thereof. Therefore, a current is allowed to flow through the inductor 124 so that a magnetic force can be used in the alignment as described above with reference to FIGS. 23A-23C.

In the fourth embodiment, only one inductor 124 is shown. However, there may be a plurality of such regions for alignment and electrical connection, each region including the inductor 124 on the first wafer Wf1′, the through via 110 under the inductor 124, the interconnect 222 (and the cap film 223) of the second wafer Wf2 corresponding to the through via 110. By performing the alignment for the plurality of regions, it is possible to perform an alignment of a better precision.

Note that the third embodiment and the fourth embodiment both illustrated examples where the first wafer Wf1 (Wf1′) and the second wafer Wf2, each having a semiconductor substrate with MOS elements, the interconnect structure, etc., provided thereon, are bonded together, to manufacture a semiconductor apparatus as an electronic device. However, the present invention is not limited thereto. For example, even where an insulating substrate having a conductive film is used, the present invention can be applied with no problems to the conductive film. Moreover, the present invention can also be applied to such a case where a structure having the enclosure interconnect 111 and the through via 110 is aligned with and mounted on a printed circuit board.

It is also possible to use a first wafer, which include both the enclosure interconnect described above in the third embodiment, and the inductor described above in the fourth embodiment.

(Description of Alignment Method and Apparatus used Therefor)

Next, an alignment method used when manufacturing an electronic device of the first to fourth embodiments, and an apparatus used therefor will be further described with reference to the drawings.

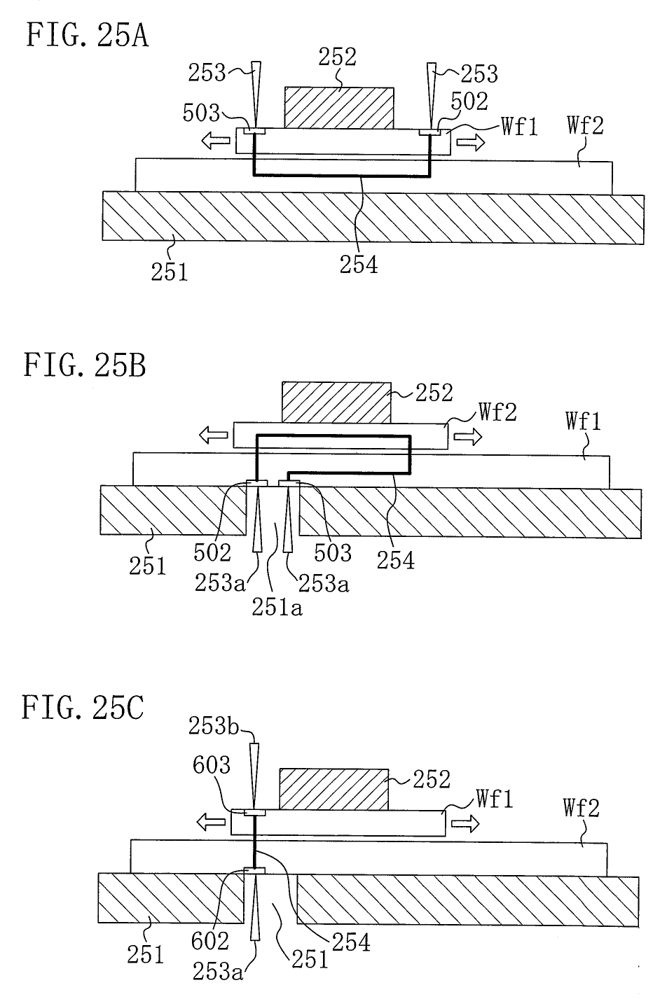

FIG. 25A is a diagram further illustrating the alignment method of the first embodiment shown in FIGS. 8 and 9. In FIG. 25A, the second wafer Wf2 is fixed on a stage 251. The stage 251 is a wafer chuck of a prober, for example, but is not limited to this. The first wafer Wf1 is held by a handler 252, and can be translated or rotated with respect to the principal surface of the second wafer Wf2. In FIG. 25A, the handler 252 includes probes 253, and the probes 253 are connected respectively to the connection pads 502 and 503 on the first wafer Wf1.

The first wafer Wf1 is moved while applying a voltage through the probe 253, and the position at which the current value of the current flowing through a current path 254 including interconnects, through vias, etc., is maximized is determined as the optimal position, as described above in the first embodiment.

Next, the alignment described above in the first embodiment can also be performed as shown in FIG. 25B. With this method, the arrangement is upside down from that shown in FIG. 8. That is, the first wafer Wf1 is fixed to the stage 251 so that the surface including the connection pads 502 and 503 formed thereon is facing down. An opening 251a is provided in the stage 251, thereby exposing the connection pads 502 and 503. Moreover, probes 253a are connected respectively to the connection pads 502 and 503 in the opening 251a.

The second wafer Wf2 is held by the handler 252 with the side of the semiconductor substrate 201 facing up so that it can be translated or rotated.

The second wafer Wf2 is moved while applying a voltage through the probe 253a, and the position at which the current value of the current flowing through the current path 254 is maximized is determined as the optimal position.

Next, FIG. 25C is a diagram further illustrating the alignment method of the second embodiment shown in FIG. 12. In FIG. 25C, the second wafer Wf2 is fixed on the stage 251. Now, the opening 251a is provided in the stage 251, thereby exposing a semiconductor region 602 of the second wafer Wf2. Moreover, the probe 253a is connected to the semiconductor region 602 in the opening 251a.

The first wafer Wf1 is held by the handler 252, and a probe 253b, which the handler 252 is provided with, is connected to the connection pad 603.

The first wafer Wf1 is moved while applying a voltage through the probes 253a and 253b, and the position at which the current value of the current flowing through the current path 254 is maximized is determined as the optimal position as described above in the second embodiment.

As described above, with the method described above with reference to FIGS. 25A-25C, at least one of the stage 251 and the handler 252 is provided with the probe 253 (253a, 253b) for making an electrical connection with the first wafer Wf1 and the second wafer Wf2.

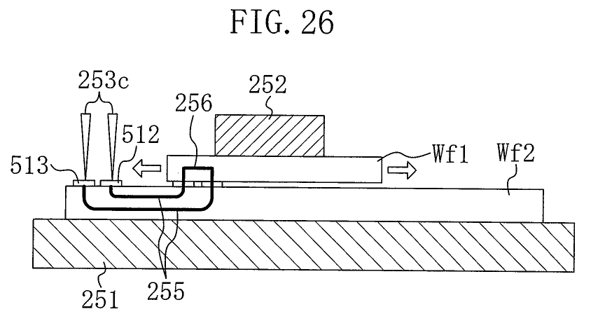

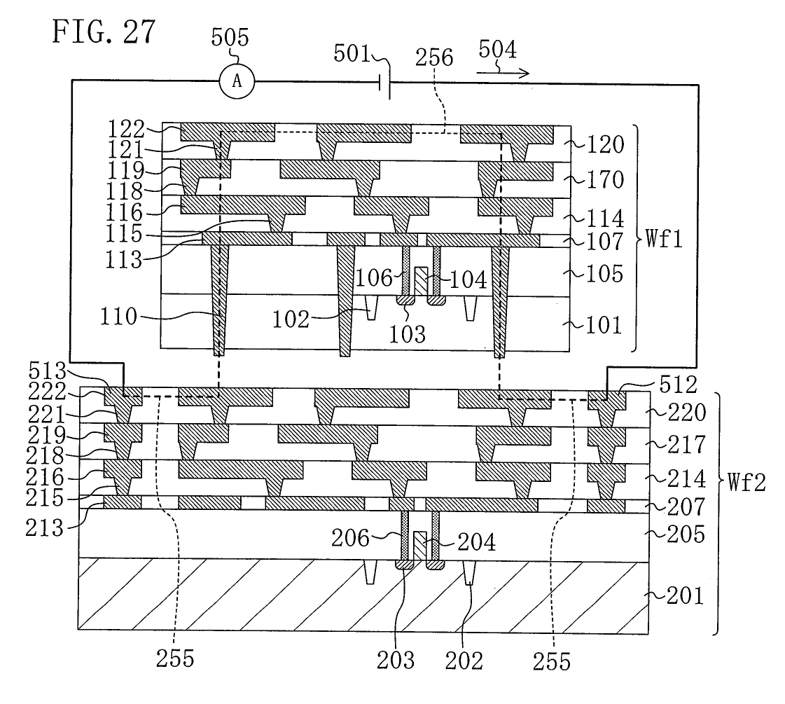

In contrast, FIG. 26 shows a method with which the stage 251 and the handler 252 of an ordinary type can be used. In such a case, the first wafer Wf1 and the second wafer Wf2 shown in FIG. 27 are used.

In FIG. 27, some interconnects on the uppermost layer of the second wafer Wf2 serve as the connection pads 502 and 503. A current path 255 including interconnects, vias, etc., is formed in the second wafer Wf2, and a current path 256 including through vias, vias, interconnects, etc., is formed in the first wafer Wf1. Now, the terminal of the power supply 501 (a probe 253c in FIG. 26) is connected to the connection pads 502 and 503 and a voltage is applied thereto while the first wafer Wf1 is moved. The position at which the current value of the current flowing through the current paths 255 and 256 is maximized is determined as the optimal position.

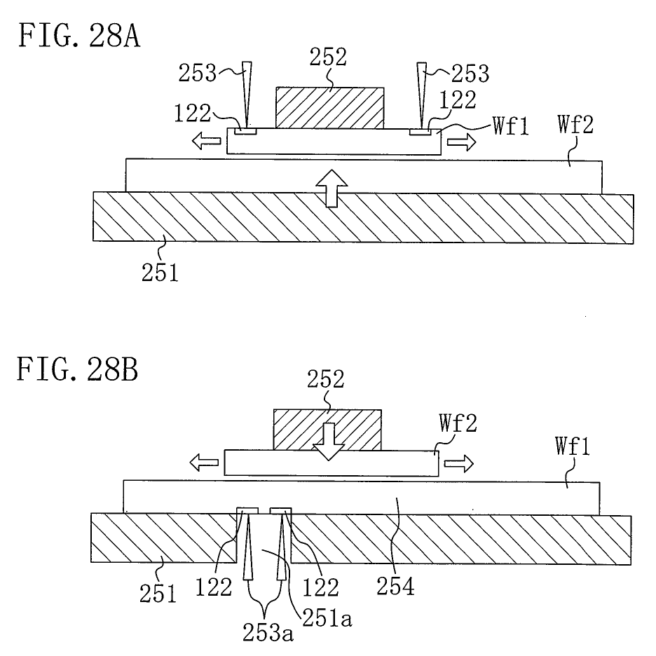

Next, FIG. 28A is a diagram further illustrating the alignment method of the third embodiment shown in FIGS. 17A and 17B. In FIG. 28A, the second wafer Wf2 is fixed on a stage 251. The stage 251 is a wafer chuck of a prober, for example, but is not limited to this. The first wafer Wf1 is held by the handler 252, and can be translated or rotated with respect to the principal surface of the second wafer Wf2. In FIG. 28A, the handler 252 includes the probes 253, and the probes 253 are electrically connected to the enclosure interconnect 111 of the first wafer Wf1 (see FIG. 17B).

When a current is allowed to flow through the enclosure interconnect 111 via the probes 253, the through via 110 has a magnetic force, and therefore the stage 251 and the second wafer Wf2 are drawn toward the first wafer Wf1 and are displaced in the direction vertical to the second wafer Wf2. The first wafer Wf1 is moved while observing such displacement, and the position at which the displacement is maximized is determined as the optimal position as described above in the third embodiment.

Next, the alignment described above in the first embodiment can also be performed as shown in FIG. 28B. With this method, the arrangement is upside down from that shown in FIG. 17A. That is, the first wafer Wf1 is fixed to the stage 251 so that the surface including the interconnect 122 of the uppermost layer formed thereon is facing down. The opening 251a is provided in the stage 251, thereby exposing the interconnect 122. Moreover, one probe 253a is connected to each interconnect 122 in the opening 251a.

The second wafer Wf2 is held by the handler 252 with the side of the semiconductor substrate 201 facing up so that it can be translated or rotated.

When a current is allowed to flow through the enclosure interconnect 111 of the first wafer Wf1 via the probe 253a, the second wafer Wf2 is displaced by being drawn by the magnetic force generated in the through via 110. The first wafer Wf1 is moved while observing such displacement, and the position at which the displacement is maximized is determined as the optimal position.

As described above, with the method described above with reference to FIGS. 28A and 28B, at least one of the stage 251 and the handler 252 is provided with the probe 253 (253a) for making an electrical connection with the first wafer Wf1 and the second wafer Wf2.

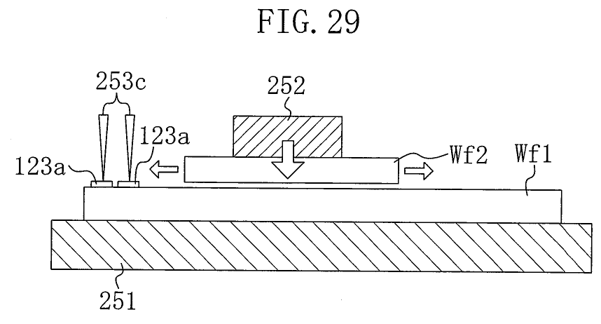

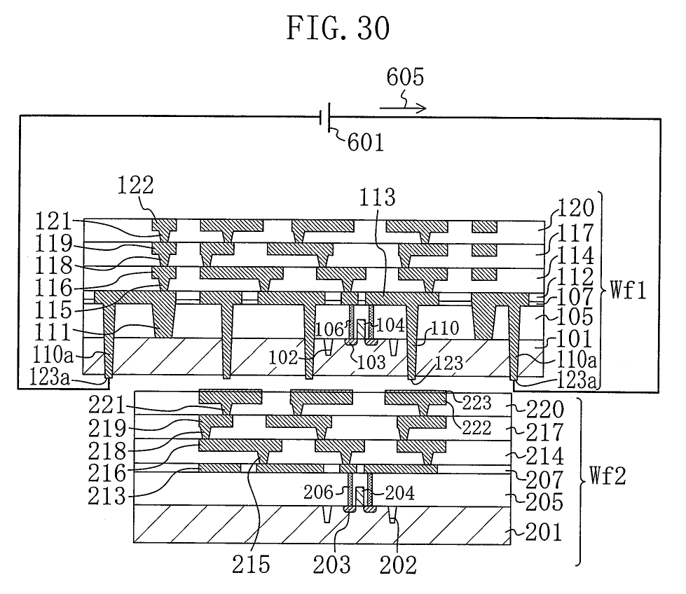

In contrast, FIG. 29 shows a method with which the stage 251 and the handler 252 of an ordinary type can be used. In such a case, the first wafer Wf1 and the second wafer Wf2 shown in FIG. 30 are used.

In FIG. 30, there is provided a through via 110a electrically connected to the enclosure interconnect 111 of the first wafer Wf1, with a through via bottom 123a exposed from the semiconductor substrate 101. The terminal of the power supply 601 (the probe 253c in FIG. 29) is connected to the through via bottom 123a so as to allow a current to flow through the enclosure interconnect 111.

As shown in FIG. 29, the first wafer Wf1 is fixed to the stage 251 with the side of the semiconductor substrate 101 facing up. The second wafer Wf2 is held by the handler 252 with the side of the interconnect 222 and the cap film 223 of the uppermost layer facing down.

A current is allowed to flow through the enclosure interconnect 111 of the first wafer Wf1 via the probe 253c, and the second wafer Wf2 is moved while observing displacement caused by the generated magnetic force, so that the position at which the displacement is maximized is determined ad the optimal position.

The electronic device and the method for manufacturing the same described above are also useful as a semiconductor apparatus whose packaging density is increased by further reducing the size and the thickness thereof because they realize, with a good yield, a layered structure (three-dimensional structure) in which a plurality of substrates are aligned together accurately and reliably.

What is claimed is:

1. An electronic device comprising:
a first substrate; and
a second substrate on which the first substrate is mounted and which is electrically connected to the first substrate in at least one predetermined area, wherein
the predetermined area includes
at least two through vias running through the first substrate, and
an interconnect provided in the second substrate, and
the at least two through vias are electrically connected together via the interconnect.

2. The electronic device of claim 1, wherein
at least two conductive portions are formed in an uppermost layer of the first substrate, and
the at least two through vias are electrically connected to the at least two conductive portions respectively and separately.

3. The electronic device of claim 1, wherein
the at least two through vias are formed in a peripheral portion within the predetermined area.

4. The electronic device of claim 1, comprising
a plurality of pairs of the through vias.

5. An electronic device comprising:
a first substrate; and
a second substrate on which the first substrate is mounted and which is electrically connected to the first substrate in at least one predetermined area, wherein
the predetermined area includes
at least one first through via running through the first substrate, and
at least one second through via running through the second substrate, and
the at least one first through via and the at least one second through via are electrically connected together.

6. The electronic device of claim 5, wherein
a first conductive portion is provided in an uppermost layer of the first substrate,
a second conductive portion is provided in an uppermost layer of the second substrate, and
the first conductive portion, the first through via, the second conductive portion and the second through via are electrically connected together.

7. The electronic device of claim 5, wherein
the first through via and the second through via are formed in an peripheral portion within the predetermined area.

8. The electronic device of claim 5, comprising
a plurality of pairs of the first through vias and the second through vias.

9. An electronic device comprising:
a first substrate; and
a second substrate on which the first substrate is mounted and which is electrically connected to the first substrate in at least one predetermined area, wherein
the predetermined area includes
at least one first through via running through the first substrate,
a device isolation region formed in a semiconductor substrate of the second substrate, and
at least one plug formed so as to be connected to the semiconductor substrate of the second substrate,
the device isolation region is formed so as to surround a position of a lower end portion of the plug, and
the at least one first through via and the at least one plug are electrically connected together.

10. The electronic device of claim 9, wherein
a first conductive portion is provided in an uppermost layer of the first substrate,
a second conductive portion is provided in an uppermost layer of the second substrate, and
the first conductive portion, the first through via, the second conductive portion and the plug are electrically connected together.

11. The electronic device of claim 9, wherein
the first through via and the plug are formed in a peripheral portion within the predetermined area.

12. The electronic device of claim 9, comprising
a plurality of pairs of the first through vias and the plugs.

13. A method for manufacturing an electronic device comprising the steps of:
(a) forming at least two through vias in a first substrate;
(b) forming an interconnect in a second substrate; and
(c) bonding together the first substrate and the second substrate, after the step (a) and the step (b), wherein
the at least two through vias are electrically connected together via the interconnect.

14. The method for manufacturing an electronic device of claim 13, wherein
in the step (c), a current is allowed to flow through the at least two through vias via the interconnect, and the bonding is performed while observing a current value thereof.

15. A method for manufacturing an electronic device comprising the steps of:
(a) forming at least one first through via in a first substrate;
(b) forming at least one second through via in a second substrate; and
(c) bonding together the first substrate and the second substrate after the step (a) and the step (b), wherein
the at least one first through via and the at least one second through via are electrically connected together.

16. The method for manufacturing an electronic device of claim 15, wherein
in the step (c), a current is allowed to flow through the first through via and the second through via, and the bonding is performed while observing a current value thereof.

17. A method for manufacturing an electronic device comprising the steps of:
(a) forming at least one first through via in a first substrate;
(b) forming a device isolation region in a semiconductor substrate of a second substrate;
(c) forming at least one plug so as to be connected to the semiconductor substrate of the second substrate; and
(d) bonding together the first substrate and the second substrate after the step (a) and the step (b), wherein
the device isolation region is formed so as to surround a position of a lower end portion of the plug, and
the at least one first through via and the at least one plug are electrically connected together.

18. The method for manufacturing an electronic device of claim 17, wherein
in the step (d), a current is allowed to flow through the first through via and the plug, and the bonding is performed while observing a current value thereof.
